(19) United States
(12) Patent Application Publication
(10) Pub. No.: US 2026/0297406 A1
(43) Pub. Date: Oct. 1, 2026

(54) CHEMICAL-MECHANICAL POLISHING COMPOSITION CONTAINING SILICA AND CERIA ABRASIVES

(71) Applicant: ENTEGRIS, INC., Billerica, MA (US)

(72) Inventors: Elliot Knapton, Aurora, IL (US); Brian Reiss, Woodridge, IL (US); Lung-Tai Lu, Kaohsiung City (TW)

(21) Appl. No.: 19/567,621

(22) Filed: Mar. 16, 2026

Related U.S. Application Data
(60) Provisional application No. 63/780,047, filed on Mar. 28, 2025.

(51) Int. Cl. C09K 3/14; H10P 52/40

(52) U.S. Cl. CPC C09K 3/1463; H10P 52/402; H10P 52/407

(57) ABSTRACT

The invention provides a chemical-mechanical polishing composition comprising: (a) silica abrasive particles comprising an aminosilane compound, a phosphonium silane compound, or a combination thereof incorporated (i) on an outer surface thereof and/or (ii) internal to an outer surface thereof, (b) ceria abrasive particles, and (c) water. The invention also provides a method of chemically-mechanically polishing a substrate using said composition.

### BACKGROUND OF THE INVENTION

In the fabrication of integrated circuits and other electronic devices, multiple layers of conducting, semiconducting, and dielectric materials are deposited onto or removed from a substrate surface. As layers of materials are sequentially deposited onto and removed from the substrate, the uppermost surface of the substrate may become non-planar and require planarization. Planarizing a surface, or “polishing” a surface, is a process where material is removed from the surface of the substrate to form a generally even, planar surface. Planarization is useful in removing undesired surface topography and surface defects, such as rough surfaces, agglomerated materials, crystal lattice damage, scratches, and contaminated layers or materials. Planarization also is useful in forming features on a substrate by removing excess deposited material used to fill the features and to provide an even surface for subsequent levels of metallization and processing.

Compositions and methods for planarizing or polishing the surface of a substrate are well known in the art. Chemical-mechanical planarization, or chemical-mechanical polishing (CMP), is a common technique used to planarize substrates. CMP utilizes a chemical composition, known as a CMP composition or more simply as a polishing composition (also referred to as a polishing slurry), for selective removal of material from the substrate. Polishing compositions typically are applied to a substrate by contacting the surface of the substrate with a polishing pad (e.g., polishing cloth or polishing disk) saturated with the polishing composition. The polishing of the substrate typically is further aided by the chemical activity of the polishing composition and/or the mechanical activity of an abrasive suspended in the polishing composition or incorporated into the polishing pad (e.g., fixed abrasive polishing pad).

A polishing composition can be characterized according to its polishing rate (i.e., removal rate) and its planarization efficiency. The polishing rate refers to the rate of removal of a material from the surface of the substrate and is usually expressed in terms of units of length (thickness) per unit of time (e.g., Angstroms (Å) per minute). Planarization efficiency relates to step height reduction versus amount of material removed from the substrate. Specifically, a polishing surface, e.g., a polishing pad, first contacts the “high points” of the surface and must remove material in order to form a planar surface. A process that results in achieving a planar surface with less removal of material is considered to be more efficient than a process requiring removal of more material to achieve planarity.

Many different abrasives (e.g., ceria abrasives or silica abrasives) can be used for CMP. Ceria-based CMP compositions often provide high tetraethyl orthosilicate (TEOS) removal rates, but may not be able to provide the necessary selectivity for advanced nodes in logic and memory applications. Silica-based CMP compositions may not provide the as high TEOS removal rates as ceria-based CMP compositions, but silica-based CMP compositions can provide different selectivity, improved defectivity, and increased colloidal stability. Since ceria-based CMP compositions and silica-based CMP compositions each provide different benefits, blending ceria and silica may provide performance advantages relative to each of the abrasives individually. However, due to stability issues, CMP compositions containing a blend of ceria abrasive and silica abrasive have not been commercially implemented.

Thus, a need remains for compositions and methods for chemical-mechanical polishing, which utilize colloidally stable blends of ceria abrasive and silica abrasive, to provide high TEOS removal rates, while providing tunable selectivity on other materials such as, for example, silicon nitride (SiN) and polysilicon. The invention provides such polishing compositions and methods. These and other advantages of the invention, as well as additional inventive features, will be apparent from the description of the invention provided herein.

### BRIEF SUMMARY OF THE INVENTION

The invention provides a chemical-mechanical polishing composition comprising: (a) silica abrasive particles comprising an aminosilane compound, a phosphonium silane compound, or a combination thereof incorporated (i) on an outer surface thereof and/or (ii) internal to an outer surface thereof, (b) ceria abrasive particles, and (c) water.

The invention further provides a method of chemically-mechanically polishing a substrate comprising: (i) providing a substrate, (ii) providing a polishing pad, (iii) providing a chemical-mechanical polishing composition comprising: (a) silica abrasive particles comprising an aminosilane compound, a phosphonium silane compound, or a combination thereof incorporated (i) on an outer surface thereof and/or (ii) internal to an outer surface thereof, (b) ceria abrasive particles, and (c) water, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

### BRIEF DESCRIPTION OF THE DRAWINGS

FIG. 1 is a graph showing the particle size analysis of Polishing Composition 4A, as described in Example 4.

FIG. 2A is a chart showing the stability of Polishing Composition 5A, as measured by the pH, conductivity (μS/cm), particle size (nm), and zeta potential (mV) over a period of 8 weeks, as described in Example 5.

FIG. 2B is a chart showing the stability of Polishing Composition 5B, as measured by the pH, conductivity (μS/cm), particle size (nm), and zeta potential (mV) over a period of 8 weeks, as described in Example 5.

FIG. 2C is a chart showing the stability of Polishing Composition 5C, as measured by the pH, conductivity (μS/cm), particle size (nm), and zeta potential (mV) over a period of 8 weeks, as described in Example 5.

FIG. 2D is a chart showing the stability of Polishing Composition 5D, as measured by the pH, conductivity (μS/cm), particle size (nm), and zeta potential (mV) over a period of 8 weeks, as described in Example 5.

FIG. 2E is a chart showing the stability of Polishing Composition 5E, as measured by the pH, conductivity (μS/cm), particle size (nm), and zeta potential (mV) over a period of 8 weeks, as described in Example 5.

### DETAILED DESCRIPTION OF THE INVENTION

The invention provides a chemical-mechanical polishing composition comprising: (a) silica abrasive particles comprising an aminosilane compound, a phosphonium silane compound, or a combination thereof incorporated (i) on an outer surface thereof and/or (ii) internal to an outer surface thereof, (b) ceria abrasive particles, and (c) water. In other words, the chemical-mechanical polishing composition comprises both silica abrasive particles and ceria abrasive particles. In some embodiments, the chemical-mechanical polishing composition does not contain silica-modified ceria abrasive particles, does not contain ceria-modified silica abrasive particles, or does not contain silica-modified ceria abrasive particles and does not contain ceria-modified silica abrasive particles.

The chemical-mechanical polishing composition comprises silica abrasive particles comprising an aminosilane compound, a phosphonium silane compound, or a combination thereof incorporated (i) on an outer surface thereof and/or (ii) internal to an outer surface thereof. As used herein, the terms “silica abrasive,” “silica abrasive particle,” and “silica particle” can be used interchangeably, and can refer to any silica particle comprising an aminosilane compound, a phosphonium silane compound, or a combination thereof incorporated (i) on an outer surface thereof and/or (ii) internal to an outer surface thereof.

In some embodiments, the silica abrasive particles are colloidal silica particles. In other words, in some embodiments, the silica abrasive particles preferably are colloidally stable in the polishing composition. The term colloid refers to the suspension of particles in the liquid carrier (e.g., water). Colloidal stability refers to the maintenance of that suspension through time. In the context of this invention, an abrasive is considered colloidally stable if, when the abrasive is placed into a 100 mL graduated cylinder and allowed to stand unagitated for a time of 2 hours, the difference between the concentration of particles in the bottom 50 mL of the graduated cylinder ([B] in terms of g/mL) and the concentration of particles in the top 50 mL of the graduated cylinder ([T] in terms of g/mL) divided by the initial concentration of particles in the abrasive composition ([C] in terms of g/mL) is less than or equal to 0.5 (i.e., {[B]-[T]}/[C]≤0.5). More preferably, the value of {[B]-[T]}/[C] is less than or equal to 0.3, and most preferably is less than or equal to 0.1.

In some embodiments, the colloidal silica particles are prepared via a wet process rather than a pyrogenic or flame hydrolysis process which produces structurally different particles. A suitable dispersion may include both aggregated and non-aggregated colloidal silica particles. As is known to those of ordinary skill in the art, non-aggregated particles are individually discrete particles that may be spherical or nearly spherical in shape, but can have other shapes as well. These non-aggregated particles are referred to as primary particles. Aggregated particles are particles in which multiple discrete particles (primary particles) have clustered or bonded together to form aggregates having generally irregular shapes. Aggregated particles may include two, three, or more connected primary particles.

The silica abrasive particles (e.g., colloidal silica abrasive particles) comprise an aminosilane compound, a phosphonium silane compound, or a combination thereof incorporated (i) on an outer surface thereof and/or (ii) internal to an outer surface thereof.

In some embodiments, the silica abrasive particles (e.g., colloidal silica abrasive particles) comprise an aminosilane compound, a phosphonium silane compound, or a combination thereof incorporated on an outer surface thereof. As used herein, the phrase “on an outer surface thereof” means that the aminosilane compound is covalently bonded to or chemically attached to the surface of the colloidal silica abrasive particle, for example, via a condensation reaction between (a) the silane group(s) in the modifying aminosilane compound or phosphonium silane compound and (b) the surface silanol group(s) on the colloidal silica abrasive particle. For example, the silica abrasive particles (e.g., colloidal silica abrasive particles) comprising an aminosilane compound, a phosphonium silane compound, or a combination thereof can be prepared by the methods described in U.S. Pat. No. 9,422,456, which is hereby incorporated by reference herein.

In some embodiments, the silica abrasive particles (e.g., colloidal silica abrasive particles) comprise an aminosilane compound, a phosphonium silane compound, or a combination thereof incorporated internal to an outer surface thereof. Colloidal silica abrasive particles having an aminosilane compound, a phosphonium silane compound, or a combination thereof incorporated internal to an outer surface thereof may be fabricated, for example, by growing the abrasive particles in a liquid solution containing the aminosilane compound or phosphonium silane compound such that the aminosilane compound or phosphonium silane compound becomes incorporated into at least a portion of the colloidal silica particles during growth thereof. Such abrasive particles may alternatively be fabricated via treating a conventional colloidal silica particle with the aminosilane compound or phosphonium silane compound and then growing additional silica over the aminosilane compound or phosphonium silane compound (and thereby covering the aminosilane compound or phosphonium silane compound with additional silica). When the aminosilane compound or phosphonium silane compound is incorporated internally in the colloidal silica abrasive particles, it will be understood that a portion of the chemical species may also be at or near the particle surface (such that the chemical species may be both internal to the surface and at the surface).

In certain embodiments, the silica abrasive particles have a core-shell structure wherein an outer shell is disposed over an inner core, and the aminosilane compound and/or the phosphonium silane compound is incorporated within the outer shell. In other words, the aminosilane compound, the phosphonium silane compound, or the combination thereof is incorporated internal to an outer surface (i.e., inside the outer shell) of the silica abrasive particle. The outer shell can have any suitable thickness. In some embodiments the outer shell has a thickness of at least 1 nm (e.g., 1 nm to 50 nm, 1 nm to 20 nm, 1 nm to 10 nm, or 1 nm to 5 nm).

In some embodiments, the silica abrasive particles (e.g., colloidal silica abrasive particles) comprise an aminosilane compound incorporated (i) on an outer surface thereof and/or (ii) internal to an outer surface thereof. The aminosilane compound can be any suitable aminosilane compound, including, for example, primary aminosilanes, secondary aminosilanes, tertiary aminosilanes, quaternary aminosilanes, and multi-podal (e.g., dipodal) aminosilanes. For example, the aminosilane compound can be any suitable aminosilane compound selected from bis(2-hydroxyethyl)-3-aminopropyl trialkoxysilane (e.g., bis(2-hydroxyethyl)-3-aminopropyl trimethoxysilane), diethylaminomethyltrialkoxysilane (e.g., diethylaminomethyltrimethoxysilane), (N,N-diethyl-3-aminopropyl)trialkoxysilane (e.g., (N,N-diethyl-3-aminopropyl)trimethoxysilane), 3-(N-styrylmethyl-2-aminoethylamino)propyltrialkoxysilane (e.g., 3-(N-styrylmethyl-2-aminoethylamino)propyltrimethoxysilane), aminopropyl trialkoxysilane (e.g., aminopropyl trimethoxysilane), N-(2-N-benzylaminoethyl)-3-aminopropyltrialkoxysilane (e.g., N-(2-N-benzylaminoethyl)-3-aminopropyltrimethoxysilane), trialkoxysilyl propyl-N,N,N-trimethyl ammonium (e.g., trimethoxysilyl propyl-N,N,N-trimethyl ammonium), N-(trialkoxysilylethyl)benzyl-N,N,N-trimethyl ammonium (e.g., N-(trimethoxysilylethyl)benzyl-N,N,N-trimethyl ammonium), (bis(methyldialkoxysilylpropyl)-N-methyl amine, bis(trialkoxysilylpropyl)urea, bis(3-(trialkoxysilyl)propyl)-ethylenediamine, bis(trialkoxysilylpropyl)amine, bis(trialkoxysilylpropyl)amine, 3-aminopropyltrialkoxysilane, N-(2-aminoethyl)-3-aminopropylmethyldialkoxysilane, N-(2-aminoethyl)-3-aminopropyltrialkoxysilane, 3-aminopropylmethyldialkoxysilane, 3-aminopropyltrialkoxysilane, (N-trialkoxysilylpropyl)polyethyleneimine, trialkoxysilylpropyldiethylenetriamine, N-phenyl-3-aminopropyltrialkoxysilane, N-(vinylbenzyl)-2-aminoethyl-3-aminopropyltrialkoxysilane, 4-aminobutyltrialkoxysilane, salts thereof, and mixtures thereof. In certain embodiments, the aminosilane compound is a multi-podal (e.g., dipodal) aminosilane, such as, for example, bis(trialkoxysilyl)ethane, bis(trialkoxysilylalkyl)amine (e.g., bis(trialkoxysilylalkyl)amine or bis(trialkoxysilylpropyl) amine), N-(hydroxyalkyl)-N,N-bis(trialkoxysilylalkyl)amine, N,N′-bis[(3-trialkoxysilyl)alkyl]ethylenediamine, N,N′-bis(2-hydroxyalkyl)-N,N′-bis(trialkoxysilylalkyl)ethylenediamine, tris(trialkoxysilylalkyl)amine, 1,11-bis(trialkoxysilyl)-4-oxa-8-azaundecan-6-ol, salts thereof, or mixtures thereof. In any of the foregoing exemplary aminosilane compounds, the alkyl or alkoxy substituent can be any linear or branched C₁₋₆ alkyl or alkoxy group. In certain embodiments, the aminosilane compound is a propyl group containing aminosilane or an aminosilane compound including a propyl amine.

Those of ordinary skill in the art will readily appreciate that aminosilane compounds are commonly hydrolyzed (or partially hydrolyzed) in an aqueous medium. Thus by reciting an aminosilane compound, it will be understood that the aminosilane and/or a hydrolyzed (or partially hydrolyzed) species and/or condensed species thereof may be incorporated in the silica abrasive particles (e.g., the colloidal silica abrasive particles).

In embodiments where the silica abrasive particles (e.g., colloidal silica abrasive particles) comprise an aminosilane compound incorporated (i) on an outer surface thereof and/or (ii) internal to an outer surface thereof, a molar ratio of the aminosilane compound to silica in the silica abrasive particles (e.g., the colloidal silica abrasive particles) is preferably less than about 10% (e.g., less than about 8%, less than about 6%, less than about 5%, less than about 4%, or less than about 2%). The molar ratio is also preferably (although not necessarily) greater than about 0.1% (e.g., greater than about 0.2% or greater than about 0.3%). In some embodiments, the molar ratio of the aminosilane compound to silica in the silica abrasive particles is less than 10% (e.g., 0.1% to 10%, 0.2% to 10%, or 0.3% to 10%). In certain embodiments, the molar ratio of the aminosilane compound to silica in the silica abrasive particles is less than 5% (e.g., 0.1% to 5%, 0.2% to 5%, or 0.3% to 5%). In some embodiments, wherein the silica abrasive particles comprising the aminosilane compound have a molar ratio of the aminosilane compound to silica of less than 10%. In certain embodiments, wherein the silica abrasive particles comprising the aminosilane compound have a molar ratio of the aminosilane compound to silica of less than 5%.

Those of ordinary skill in the art will understand that the molar ratio of the aminosilane compound to silica in the silica abrasive particles (e.g., the colloidal silica abrasive particles) may be approximately equal to the molar ratio of the aminosilane compound to the silica producing compound in the liquid solution in which the silica abrasive particles (e.g., the colloidal silica abrasive particles) are grown.

In some embodiments, the silica abrasive particles (e.g., colloidal silica abrasive particles) comprise a phosphonium silane compound incorporated (i) on an outer surface thereof and/or (ii) internal to an outer surface thereof. The phosphonium silane compound can be any suitable phosphonium silane compound. Those of ordinary skill in the art will readily appreciate that phosphonium silane compounds are commonly hydrolyzed (or partially hydrolyzed) in an aqueous medium. Thus by reciting a phosphonium silane compound, it will be understood that the phosphonium silane and/or a hydrolyzed (or partially hydrolyzed) species and/or condensed species thereof may be incorporated in the silica abrasive particles (e.g., the colloidal silica abrasive particles).

In embodiments where the silica abrasive particles (e.g., colloidal silica abrasive particles) comprise a phosphonium silane compound incorporated (i) on an outer surface thereof and/or (ii) internal to an outer surface thereof, a molar ratio of the phosphonium silane compound to silica in the silica abrasive particles (e.g., the colloidal silica abrasive particles) is preferably less than about 10% (e.g., less than about 8%, less than about 6%, less than about 5%, less than about 4%, or less than about 2%). The molar ratio is also preferably (although not necessarily) greater than about 0.1% (e.g., greater than about 0.2% or greater than about 0.3%). In some embodiments, the molar ratio of the phosphonium silane compound to silica in the silica abrasive particles is less than 10% (e.g., 0.1% to 10%, 0.2% to 10%, or 0.3% to 10%). In certain embodiments, the molar ratio of the phosphonium silane compound to silica in the silica abrasive particles is less than 5% (e.g., 0.1% to 5%, 0.2% to 5%, or 0.3% to 5%). In some embodiments, wherein the silica abrasive particles comprising the phosphonium silane compound have a molar ratio of the phosphonium silane compound to silica of less than 10%. In certain embodiments, wherein the silica abrasive particles comprising the phosphonium silane compound have a molar ratio of the phosphonium silane compound to silica of less than 5%.

Those of ordinary skill in the art will understand that the molar ratio of the phosphonium silane compound to silica in the silica abrasive particles (e.g., the colloidal silica abrasive particles) may be approximately equal to the molar ratio of the phosphonium silane compound to the silica producing compound in the liquid solution in which the silica abrasive particles (e.g., the colloidal silica abrasive particles) are grown.

In some embodiments, the silica abrasive particles (e.g., the colloidal silica abrasive particles) further comprise an alkali catalyst incorporated internal to an outer surface thereof. The alkali catalyst can be any compound selected from an ether amine, an ethylene amine, a tetraalkyl amine, and/or an alcohol amine. Exemplary alkali catalysts include, for example, ethylenediamine, diethylenetriamine, triethylenetetramine, ammonia, urea, monoethanolamine, diethanolamine, triethanolamine, tetramethylammonium hydroxide (TMAH), tetramethylguanidine, tetraethylammonium hydroxide, aminopropylmorpholine, hexyloxypropylamine, ethyloxypropylamine (EOPA), jeffamine HK-511, or combinations thereof. In certain embodiments, the alkali catalyst is a nitrogen-containing alkali catalyst, preferably having from 1 to 6 carbon atoms. In some embodiments, the alkali catalyst is tetramethylammonium hydroxide or ethyloxypropylamine.

In some embodiments, the silica abrasive particles (e.g., the colloidal silica abrasive particles) have a permanent positive charge in the polishing composition. The charge on dispersed particles such as colloidal silica particles is commonly referred to in the art as the zeta potential (or the electrokinetic potential). The zeta potential of a particle refers to the electrical potential difference between the electrical charge of the ions surrounding the particle and the electrical charge of the bulk solution of the polishing composition (e.g., the liquid carrier and any other components dissolved therein). The zeta potential is typically dependent on the pH of the aqueous medium. For a given polishing composition, the isoelectric point of the particles is defined as the pH at which the zeta potential is zero. As the pH is increased or decreased away from the isoelectric point, the surface charge (and hence the zeta potential) is correspondingly decreased or increased (to negative or positive zeta potential values). The zeta potential of a dispersion such as a polishing composition may be obtained using the Model DT-1202 Acoustic and Electro-acoustic spectrometer available from Dispersion Technologies, Inc. (Bedford Hills, N.Y.) or with electrophoretic light scattering using a Malvern Zetasizer available from Malvern Panalytical (Malvern, United Kingdom).

In some embodiments, the silica abrasive particles (e.g., the colloidal silica abrasive particles) have a positive zeta potential. As used herein, the phrase “positive zeta potential,” when referring to the silica abrasive particles, refers to a silica abrasive that exhibits a positive surface charge when measured in the polishing composition without the ceria abrasive particles. In some embodiments, the silica abrasive has a zeta potential of greater than 0 mV when measured in the polishing composition, i.e., the silica abrasive has a positive zeta potential when measured in the polishing composition. For example, the silica abrasive particles (e.g., the colloidal silica abrasive particles) can have a zeta potential of at least about 10 mV in the chemical-mechanical polishing composition, a zeta potential of at least about 11 mV in the chemical-mechanical polishing composition, a zeta potential of at least about 12 mV in the chemical-mechanical polishing composition, a zeta potential of at least about 13 mV in the chemical-mechanical polishing composition, a zeta potential of at least about 14 mV in the chemical-mechanical polishing composition, a zeta potential of at least about 15 mV in the chemical-mechanical polishing composition, a zeta potential of at least about 20 mV in the chemical-mechanical polishing composition, a zeta potential of at least about 25 mV in the chemical-mechanical polishing composition, or a zeta potential of at least about 30 mV in the chemical-mechanical polishing composition.

In some embodiments, the silica abrasive particles (e.g., the colloidal silica abrasive particles) have a positive zeta potential of from about 0 mV to about 50 mV, e.g., from about 10 mV to about 50 mV, from about 11 mV to about 50 mV, from about 12 mV to about 50 mV, from about 13 mV to about 50 mV, from about 13 mV to about 50 mV, from about 14 mV to about 50 mV, from about 15 mV to about 50 mV, from about 15 mV to about 40 mV, from about 15 mV to about 35 mV, from about 15 mV to about 30 mV, from about 15 mV to about 25 mV, from about 20 mV to about 50 mV, from about 20 mV to about 40 mV, from about 20 mV to about 35 mV, from about 20 mV to about 30 mV, or from about 15 mV to about 25 mV.

The silica abrasive particles (e.g., the colloidal silica abrasive particles) can have any suitable average particle size (i.e., average particle diameter). If the average abrasive particle size is too small, the polishing composition may not exhibit sufficient removal rate. In contrast, if the average abrasive particle size is too large, the polishing composition may exhibit undesirable polishing performance such as, for example, poor substrate defectivity. Accordingly, the silica abrasive particles (e.g., the colloidal silica abrasive particles) can have an average particle size of about 50 nm or more, about 60 nm or more, about 70 nm or more, about 80 nm or more, about 90 nm or more, or about 100 nm or more. Alternatively, or in addition, the silica abrasive particles (e.g., the colloidal silica abrasive particles) can have an average particle size of about 200 nm or less, for example, about 175 nm or less, about 150 nm or less, about 125 nm or less, about 110 nm or less, about 100 nm or less, about 90 nm or less, about 80 nm or less, about 75 nm or less. Thus, the silica abrasive can have an average particle size bounded by any two of the aforementioned endpoints.

For example, the silica abrasive particles (e.g., the colloidal silica abrasive particles) can have an average particle size of about 50 nm to about 200 nm, about 50 nm to about 150 nm, about 50 nm to about 125 nm, about 50 nm to about 110 nm, about 50 nm to about 100 nm, about 50 nm to about 75 nm, about 80 nm to about 150 nm, about 80 nm to about 125 nm, about 80 nm to about 110 nm, about 80 nm to about 100 nm, about 90 nm to about 150 nm, about 90 nm to about 125 nm, about 90 nm to about 110 nm, about 90 nm to about 100 nm, about 100 nm to about 150 nm, or about 100 nm to about 125 nm. In some embodiments, the silica abrasive has an average particle size of about 90 nm to about 150 nm. In some embodiments, the silica abrasive particles (e.g., the colloidal silica abrasive particles) have an average particle size of about 50 nm to about 150 nm. In some embodiments, the silica abrasive particles (e.g., the colloidal silica abrasive particles) have an average particle size of about 50 nm to about 100 nm. For non-spherical silica abrasive particles, the size of the particle is the diameter of the smallest sphere that encompasses the particle. The particle size of the abrasive can be measured using any suitable technique, for example, using laser diffraction techniques. Suitable particle size measurement instruments are available from e.g., Malvern Instruments (Malvern, UK).

The silica abrasive particles (e.g., the colloidal silica abrasive particles) can be present in the polishing composition in any suitable amount. If the polishing composition of the invention comprises too little abrasive, the composition may not exhibit sufficient removal rate. In contrast, if the polishing composition comprises too much abrasive then the polishing composition may exhibit undesirable polishing performance and/or may not be cost effective and/or may lack stability. The polishing composition can comprise about 10 wt. % or less of the silica abrasive particles (e.g., the colloidal silica abrasive particles), for example, about 9 wt. % or less, about 8 wt. % or less, about 7 wt. % or less, about 6 wt. % or less, about 5 wt. % or less, about 4 wt. % or less, about 3 wt. % or less, about 2 wt. % or less, about 1 wt. % or less, about 0.9 wt. % or less, about 0.8 wt. % or less, about 0.7 wt. % or less, about 0.6 wt. % or less, or about 0.5 wt. % or less of the silica abrasive particles (e.g., the colloidal silica abrasive particles). Alternatively, or in addition, the polishing composition can comprise about 0.001 wt. % or more of the silica abrasive particles (e.g., the colloidal silica abrasive particles), for example, about 0.005 wt. % or more, about 0.01 wt. % or more, 0.05 wt. % or more, about 0.1 wt. % or more, about 0.2 wt. % or more, about 0.3 wt. % or more, about 0.4 wt. % or more, about 0.5 wt. % or more, or about 1 wt. % or more of the silica abrasive particles (e.g., the colloidal silica abrasive particles). Thus, the polishing composition can comprise silica abrasive particles (e.g., the colloidal silica abrasive particles) in an amount bounded by any two of the aforementioned endpoints, as appropriate.

For example, in some embodiments, the silica abrasive particles (e.g., the colloidal silica abrasive particles) can be present in the polishing composition in an amount of from about 0.001 wt. % to about 10 wt. % of the polishing composition, e.g., about 0.001 wt. % to about 8 wt. %, about 0.001 wt. % to about 6 wt. %, about 0.001 wt. % to about 5 wt. %, about 0.001 wt. % to about 4 wt. %, about 0.001 wt. % to about 2 wt. %, about 0.001 wt. % to about 1 wt. %, about 0.01 wt. % to about 10 wt. %, about 0.01 wt. % to about 8 wt. %, about 0.01 wt. % to about 6 wt. %, about 0.01 wt. % to about 5 wt. %, about 0.01 wt. % to about 4 wt. %, about 0.01 wt. % to about 2 wt. %, about 0.01 wt. % to about 1 wt. %, about 0.05 wt. % to about 10 wt. %, about 0.05 wt. % to about 8 wt. %, about 0.05 wt. % to about 6 wt. %, about 0.05 wt. % to about 5 wt. %, about 0.05 wt. % to about 4 wt. %, about 0.05 wt. % to about 2 wt. %, about 0.05 wt. % to about 1 wt. %, about 0.1 wt. % to about 10 wt. %, about 0.1 wt. % to about 8 wt. %, about 0.1 wt. % to about 6 wt. %, about 0.1 wt. % to about 5 wt. %, about 0.1 wt. % to about 4 wt. %, about 0.1 wt. % to about 2 wt. %, about 0.1 wt. % to about 1 wt. %, about 0.5 wt. % to about 10 wt. %, about 0.5 wt. % to about 8 wt. %, about 0.5 wt. % to about 5 wt. %, about 0.5 wt. % to about 4 wt. %, about 0.5 wt. % to about 2 wt. %, about 0.5 wt. % to about 1 wt. %, about 1 wt. % to about 10 wt. %, about 1 wt. % to about 8 wt. %, about 1 wt. % to about 6 wt. %, about 1 wt. % to about 5 wt. %, about 1 wt. % to about 4 wt. %, or about 1 wt. % to about 2 wt. %. In some embodiments, the polishing composition comprises about 0.001 wt. % to about 10 wt. % of the silica abrasive particles (e.g., the colloidal silica abrasive particles). In certain embodiments, the polishing composition comprises about 0.01 wt. % to about 1 wt. % of the silica abrasive particles (e.g., the colloidal silica abrasive particles).

The chemical-mechanical polishing composition comprises ceria abrasive particles. As used herein, the terms “ceria abrasive,” “ceria abrasive particle,” and “ceria particle” can be used interchangeably, and can refer to any ceria particle. As is well known, ceria is an oxide of the rare earth metal cerium, and is also known as ceric oxide, cerium oxide (e.g., cerium (IV) oxide), or cerium dioxide. Cerium (IV) oxide (CeO₂) can be formed by calcining cerium oxalate or cerium hydroxide. Cerium also forms cerium (III) oxides such as, for example, Ce₂O₃. The ceria abrasive particles can comprise any one or more of these or other oxides of ceria.

The ceria abrasive particles can be of any suitable type. For example, the ceria abrasive particles can be calcined ceria particles, wet process-based ceria particles, fumed ceria particles, or a combination thereof. In some embodiments, the ceria abrasive particles comprise, consist essentially of, or consist of wet process-based ceria particles. In some embodiments, the ceria abrasive particles are calcined ceria particles.

As used herein, “wet process-based ceria particles” (collectively herein “wet process” ceria particles) refers to a ceria prepared by a precipitation, condensation-polymerization, or similar process (as opposed to, for example, fumed or pyrogenic ceria). A polishing composition of the invention comprising wet-process ceria particles has been found to exhibit lower defects when used to polish substrates according to a method of the invention. Without wishing to be bound to a particular theory, it is believed that wet-process ceria comprises approximately spherical ceria particles and/or smaller aggregate ceria particles, thereby resulting in lower substrate defectivity when used in the inventive method. Illustrative examples of wet-process ceria are HC30™ and HC60™ ceria commercially available from Rhodia and Hybrid-30 commercially available from ANP Co., Ltd.

In some embodiments the ceria abrasive particles (e.g., the wet process ceria abrasive particles) are calcined prior to dispersion in the polishing composition. The term “calcined” or “calcining” are used interchangeably herein to refer to the heating of the ceria particles. Calcining the ceria particles impacts their resulting crystallinity. Without wishing to be bound by any particular theory, it is believed that calcining the ceria particles at high temperatures reduces defects in the crystal lattice structure of the particles.

In some embodiments, the ceria abrasive particles (e.g., the wet process ceria abrasive particles and/or calcined ceria abrasive particles) are colloidal ceria particles. In other words, in some embodiments, the ceria abrasive particles preferably are colloidally stable in the polishing composition. The term colloid refers to the suspension of particles in the liquid carrier (e.g., water). Colloidal stability refers to the maintenance of that suspension through time.

The ceria abrasive particles can have any suitable average particle size (i.e., average particle diameter). If the average ceria abrasive particle size is too small, the polishing composition may not exhibit sufficient removal rate. In contrast, if the average ceria abrasive particle size is too large, the polishing composition may exhibit undesirable polishing performance such as, for example, poor substrate defectivity. Accordingly, the ceria abrasive particles can have an average particle size of about 10 nm or more, for example, about 15 nm or more, about 20 nm or more, about 25 nm or more, about 30 nm or more, about 35 nm or more, about 40 nm or more, about 45 nm or more, or about 50 nm or more. Alternatively, or in addition, the ceria abrasive particles can have an average particle size of about 1,000 nm or less, for example, about 750 nm or less, about 500 nm or less, about 250 nm or less, about 150 nm or less, about 100 nm or less, about 75 nm or less, or about 50 nm or less. Thus, the ceria abrasive particles can have an average particle size bounded by any two of the aforementioned endpoints. For example, the ceria abrasive particles can have an average particle size of about 10 nm to about 1,000 nm, e.g., about 10 nm to about 750 nm, about 15 nm to about 500 nm, about 20 nm to about 250 nm, about 20 nm to about 150 nm, about 25 nm to about 150 nm, about 25 nm to about 100 nm, about 50 nm to about 150 nm, or about 50 nm to about 100 nm. In some embodiments, the ceria abrasive particles have an average particle size of about 50 nm to about 150 nm. For spherical ceria abrasive particles, the size of the particle is the diameter of the particle. For non-spherical ceria particles, the size of the particle is the diameter of the smallest sphere that encompasses the particle. The particle size of the ceria abrasive particles can be measured using any suitable technique, for example, using laser diffraction techniques. Suitable particle size measurement instruments are available from, for example, Malvern Instruments (Malvern, UK).

The ceria abrasive particles (e.g., the colloidal ceria abrasive particles) can be present in the polishing composition in any suitable amount. If the polishing composition of the invention comprises too little abrasive, the composition may not exhibit sufficient removal rate. In contrast, if the polishing composition comprises too much abrasive then the polishing composition may exhibit undesirable polishing performance and/or may not be cost effective and/or may lack stability. The polishing composition can comprise about 10 wt. % or less of the ceria abrasive particles (e.g., the colloidal ceria abrasive particles), for example, about 9 wt. % or less, about 8 wt. % or less, about 7 wt. % or less, about 6 wt. % or less, about 5 wt. % or less, about 4 wt. % or less, about 3 wt. % or less, about 2 wt. % or less, about 1 wt. % or less, about 0.9 wt. % or less, about 0.8 wt. % or less, about 0.7 wt. % or less, about 0.6 wt. % or less, or about 0.5 wt. % or less of the ceria abrasive particles (e.g., the colloidal ceria abrasive particles). Alternatively, or in addition, the polishing composition can comprise about 0.001 wt. % or more of the ceria abrasive particles (e.g., the colloidal ceria abrasive particles), for example, about 0.005 wt. % or more, about 0.01 wt. % or more, 0.05 wt. % or more, about 0.1 wt. % or more, about 0.2 wt. % or more, about 0.3 wt. % or more, about 0.4 wt. % or more, about 0.5 wt. % or more, or about 1 wt. % or more of the ceria abrasive particles (e.g., the colloidal ceria abrasive particles). Thus, the polishing composition can comprise ceria abrasive particles (e.g., the colloidal ceria abrasive particles) in an amount bounded by any two of the aforementioned endpoints, as appropriate.

For example, in some embodiments, the ceria abrasive particles (e.g., the colloidal ceria abrasive particles) can be present in the polishing composition in an amount of from about 0.001 wt. % to about 10 wt. % of the polishing composition, e.g., about 0.001 wt. % to about 8 wt. %, about 0.001 wt. % to about 6 wt. %, about 0.001 wt. % to about 5 wt. %, about 0.001 wt. % to about 4 wt. %, about 0.001 wt. % to about 2 wt. %, about 0.001 wt. % to about 1 wt. %, about 0.01 wt. % to about 10 wt. %, about 0.01 wt. % to about 8 wt. %, about 0.01 wt. % to about 6 wt. %, about 0.01 wt. % to about 5 wt. %, about 0.01 wt. % to about 4 wt. %, about 0.01 wt. % to about 2 wt. %, about 0.01 wt. % to about 1 wt. %, about 0.05 wt. % to about 10 wt. %, about 0.05 wt. % to about 8 wt. %, about 0.05 wt. % to about 6 wt. %, about 0.05 wt. % to about 5 wt. %, about 0.05 wt. % to about 4 wt. %, about 0.05 wt. % to about 2 wt. %, about 0.05 wt. % to about 1 wt. %, about 0.1 wt. % to about 10 wt. %, about 0.1 wt. % to about 8 wt. %, about 0.1 wt. % to about 6 wt. %, about 0.1 wt. % to about 5 wt. %, about 0.1 wt. % to about 4 wt. %, about 0.1 wt. % to about 2 wt. %, about 0.1 wt. % to about 1 wt. %, about 0.5 wt. % to about 10 wt. %, about 0.5 wt. % to about 8 wt. %, about 0.5 wt. % to about 5 wt. %, about 0.5 wt. % to about 4 wt. %, about 0.5 wt. % to about 2 wt. %, about 0.5 wt. % to about 1 wt. %, about 1 wt. % to about 10 wt. %, about 1 wt. % to about 8 wt. %, about 1 wt. % to about 6 wt. %, about 1 wt. % to about 5 wt. %, about 1 wt. % to about 4 wt. %, or about 1 wt. % to about 2 wt. %. In some embodiments, the polishing composition comprises about 0.001 wt. % to about 10 wt. % of the ceria abrasive particles (e.g., the colloidal ceria abrasive particles). In certain embodiments, the polishing composition comprises about 0.1 wt. % to about 5 wt. % of the ceria abrasive particles (e.g., the colloidal ceria abrasive particles).

The silica abrasive particles and ceria abrasive particles can be present in the polishing composition in any suitable weight ratio. For example, the silica abrasive particles and the ceria abrasive particles can be present in a weight ratio of about 1:10 to about 10:1. In some embodiments, the silica abrasive particles and the ceria abrasive particles are present in a weight ratio of about 1:10 to about 1:1 (e.g., about 1:10 to about 1:2, about 1:5 to about 1:1, about 1:5 to about 1:2, about 1:4 to about 1:1, or about 1:4 to about 1:2). In certain embodiments, the silica abrasive particles and the ceria abrasive particles are present in a weight ratio of about 1:5 to about 1:2.

The silica abrasive particles and ceria abrasive particles can have any suitable aggregate zeta potential in the polishing composition. As used herein, the phrase “aggregate zeta potential” refers to the zeta potential of the combination of the silica abrasive particles and ceria abrasive particles in the polishing composition. In some embodiments, the silica abrasive particles and ceria abrasive particles have an aggregate zeta potential of greater than 0 mV when measured in the polishing composition, i.e., the silica abrasive particles and ceria abrasive particles have a positive aggregate zeta potential when measured in the polishing composition. For example, the silica abrasive particles and ceria abrasive particles can have an aggregate zeta potential of at least about 10 mV in the chemical-mechanical polishing composition, an aggregate zeta potential of at least about 15 mV in the chemical-mechanical polishing composition, an aggregate zeta potential of at least about 20 mV in the chemical-mechanical polishing composition, an aggregate zeta potential of at least about 25 mV in the chemical-mechanical polishing composition, or an aggregate zeta potential of at least about 30 mV in the chemical-mechanical polishing composition.

In some embodiments, the silica abrasive particles and ceria abrasive particles have an aggregate zeta potential of from about 10 mV to about 50 mV, e.g., from about 15 mV to about 50 mV, from about 15 mV to about 40 mV, from about 15 mV to about 35 mV, from about 15 mV to about 30 mV, from about 15 mV to about 25 mV, from about 20 mV to about 50 mV, from about 20 mV to about 40 mV, from about 20 mV to about 35 mV, from about 20 mV to about 30 mV, from about 25 mV to about 50 mV, from about 25 mV to about 40 mV, from about 25 mV to about 35 mV, from about 25 mV to about 30 mV, or from about 15 mV to about 25 mV. In some embodiments, the silica abrasive particles and ceria abrasive particles have an aggregate zeta potential of about 20 mV to about 40 mV in the polishing composition. In certain embodiments, the silica abrasive particles and ceria abrasive particles have an aggregate zeta potential of about 25 mV to about 35 mV in the polishing composition.

The silica abrasive particles and ceria abrasive particles can have any suitable aggregate average particle size (i.e., average particle diameter) in the polishing composition. As used herein, the aggregate average particle size refers to the average particle size of the combination of the silica abrasive particles and ceria abrasive particles. Accordingly, the silica abrasive particles and ceria abrasive particles can have an aggregate average particle size of about 10 nm or more, for example, about 15 nm or more, about 20 nm or more, about 25 nm or more, about 30 nm or more, about 35 nm or more, about 40 nm or more, about 45 nm or more, about 50 nm or more, about 60 nm or more, about 70 nm or more, about 80 nm or more, about 90 nm or more, or about 100 nm or more in the polishing composition. Alternatively, or in addition, the silica abrasive particles and ceria abrasive particles can have an aggregate average particle size of about 200 nm or less, for example, about 175 nm or less, about 150 nm or less, about 125 nm or less, about 110 nm or less, about 100 nm or less, about 90 nm or less, about 80 nm or less, about 75 nm or less, about 50 nm or less, or about 40 nm or less in the polishing composition. Thus, the silica abrasive particles and ceria abrasive particles can have an aggregate average particle size bounded by any two of the aforementioned endpoints.

For example, the silica abrasive particles and ceria abrasive particles can have an aggregate average particle size of about 10 nm to about 200 nm, about 20 nm to about 200 nm, about 20 nm to about 175 nm, about 20 nm to about 150 nm, about 20 nm to about 125 nm, about 20 nm to about 110 nm, about 20 nm to about 100 nm, about 25 nm to about 125 nm, about 25 nm to about 110 nm, about 25 nm to about 100 nm, about 30 nm to about 150 nm, about 30 nm to about 100 nm, about 30 nm to about 75 nm, about 30 nm to about 40 nm, about 40 nm to about 150 nm, about 40 nm to about 125 nm, about 40 nm to about 100 nm, about 50 nm to about 150 nm, about 50 nm to about 125 nm, about 50 nm to about 110 nm, about 50 nm to about 100 nm, about 60 nm to about 150 nm, about 60 nm to about 125 nm, about 60 nm to about 110 nm, about 60 nm to about 100 nm, about 70 nm to about 150 nm, about 70 nm to about 125 nm, about 70 nm to about 110 nm, about 70 nm to about 100 nm, about 80 nm to about 150 nm, about 80 nm to about 125 nm, about 80 nm to about 110 nm, about 80 nm to about 100 nm, about 90 nm to about 150 nm, about 90 nm to about 125 nm, about 90 nm to about 110 nm, about 90 nm to about 100 nm, about 100 nm to about 150 nm, or about 100 nm to about 125 nm. In some embodiments, the silica abrasive particles and ceria abrasive particles have an aggregate average particle size of about 60 nm to about 110 nm in the polishing composition. In certain embodiments, the silica abrasive particles and ceria abrasive particles have an aggregate average particle size of about 70 nm to about 100 nm in the polishing composition.

In some embodiments, the polishing composition further comprises one or more nitrogen-containing zwitterionic compounds. The nitrogen-containing zwitterionic compounds are nitrogen-containing compounds that can be zwitterionic compounds at a particular pH. Zwitterionic compounds are neutral compounds having formal opposite charges on non-adjacent atoms. Zwitterionic compounds typically contain both an acid moiety and a base moiety, with the pKa of the acid moiety differing from the pKa of the base moiety, such that the compound is zwitterionic when the pH is between the pKa of the acid moiety and the pKa of the base moiety. Zwitterionic compounds also are referred to as inner salts. For example, amino acids (e.g., lysine) are nitrogen-containing compounds that can be zwitterionic compounds, though the nitrogen-containing compounds that can be zwitterionic compounds need not be amino acids. For example, betaine, pyridineethanesulfonic acids, pyridine sulfonic acids, pyridyl acetic acids, 3-(3-pyridyl)propionic acid, pyrazine carboxylic acid, 1-(3-sulfopropyl)pyridinium hydroxide, and picolinic acid are nitrogen-containing zwitterionic compounds. Additional nitrogen-containing compounds that can be zwitterionic compounds, which are useful in the polishing composition of the invention, include sulfanilic acid, dodecyldimethyl(3-sulfopropyl)ammonium hydroxide (lauryl sulfobetaine), (carboxymethyl)trimethylammonium hydroxide (betaine), 2-(N-morpholino)ethanesulfonic acid, N-2-acetamidoiminodiacetic acid, 1,3-bis[tris(hydroxymethyl)methylamino]propane, N-2-acetamido-2-aminoethanesulfonic acid, 3-(N-morpholine)propanesulfonic acid, N-tris(hydroxymethyl)methyl-2-aminoethanesulfonic acid, N-2-hydroxyethylpiperazine-N′-2-ethanesulfonic acid, N-2-hydroxyethylpiperazine-N′-3-propanesulfonic acid, N-tris(hydroxymethyl)methylglycine, cyclohexylaminoethanesulfonic acid, 3-(cyclohexylamino)propanesulfonic acid, 2-acrylamido-2-methylpropanesulfonic acid, salts thereof, and mixtures thereof.

The polishing composition can comprise any suitable amount of one or more nitrogen-containing zwitterionic compounds, when present. If the amount of nitrogen-containing zwitterionic compound is too low, then no beneficial effect is observed. In contrast, if the amount of the nitrogen-containing zwitterionic compound is too high, the polishing composition may exhibit undesirable polishing properties and/or may not be cost effective. The polishing composition can comprise, at the point-of-use, about 1 ppm or more of a nitrogen-containing zwitterionic compound, for example, about 5 ppm or more, about 10 ppm or more, about 15 ppm or more, about 25 ppm or more, about 50 ppm or more, about 75 ppm or more, about 100 ppm or more, about 125 ppm or more, about 150 ppm or more, about 175 ppm or more, about 200 ppm or more, about 250 ppm or more, about 300 ppm or more, about 350 ppm or more, about 400 ppm or more, about 450 ppm or more, or about 500 ppm or more of a nitrogen-containing zwitterionic compound. Alternatively, or in addition, the polishing composition can comprise about 1,000 ppm or less of a nitrogen-containing zwitterionic compound, for example, about 950 ppm or less, about 900 ppm or less, about 850 ppm or less, about 800 ppm or less, about 750 ppm or less, about 700 ppm or less, about 650 ppm or less, about 600 ppm or less, or about 550 ppm or less of a nitrogen-containing zwitterionic compound. Thus, the polishing composition can comprise one or more nitrogen-containing zwitterionic compounds in an amount bounded by any two of the aforementioned endpoints, for example, about 1 ppm to about 1000 ppm, about 5 ppm to about 950 ppm, and the like.

In a preferred embodiment, the polishing composition comprises picolinic acid. The polishing composition typically comprises about 500 ppm or less of picolinic acid at the point-of-use, for example, about 400 ppm or less, about 300 ppm or less, about 200 ppm or less, about 100 ppm or less, about 75 ppm or less, or about 50 ppm or less of picolinic acid at the point-of-use. Alternatively, or in addition, the polishing composition can comprise about 10 ppm or more of picolinic acid, for example, about 20 ppm or more, about 30 ppm or more, about 40 ppm or more, or about 50 ppm or more of picolinic acid at the point-of-use. Thus, the polishing composition can comprise picolinic acid in an amount bounded by any two of the aforementioned endpoints. For example, the polishing composition can comprise about 10 ppm to about 500 ppm of picolinic acid at the point-of-use, about 50 ppm to about 500 ppm, about 10 ppm to about 100 ppm, or about 20 ppm to about 400 ppm of picolinic acid, and the like.

The chemical-mechanical polishing composition can comprise one or more compounds capable of adjusting (i.e., that adjust) the pH of the polishing composition (i.e., pH adjusting compounds). The pH of the polishing composition can be adjusted using any suitable compound capable of adjusting the pH of the polishing composition. The pH adjusting compound desirably is water-soluble and compatible with the other components of the polishing composition. Typically, the chemical-mechanical polishing composition has a pH of about 1 to about 7 at the point-of-use (e.g., a pH of about 1 to about 6, of about 1 to about 5, of about 2 to about 7, of about 2 to about 6, of about 2 to about 5, of about 3 to about 6, about 3 to about 5, or of about 1 to about 4). Preferably, the chemical-mechanical polishing composition has a pH of about 2 to about 6 or about 3 to about 5 at the point-of-use.

The pH of the chemical-mechanical polishing composition can be adjusted using any suitable compound capable of adjusting the pH of the polishing composition. The pH adjusting compound desirably is water-soluble and compatible with the other components of the polishing composition. Non-limiting examples of suitable acids for adjusting the pH of the polishing composition include nitric acid, hydrochloric acid, sulfuric acid, phosphoric acid, and organic acids such as formic acid and acetic acid. Non-limiting examples of suitable bases for adjusting the pH of the polishing composition include sodium hydroxide, potassium hydroxide, and ammonium hydroxide.

In some embodiments, the chemical-mechanical polishing composition further comprises one or more additives such as, for example, conditioners, acids (e.g., sulfonic acids), complexing agents (e.g., anionic polymeric complexing agents), chelating agents, biocides, scale inhibitors, dispersants, and/or conductivity adjustors.

In some embodiments, the chemical-mechanical polishing composition further comprises a biocide. A biocide, when present, can be any suitable biocide and can be present in the polishing composition in any suitable amount. For example, the biocide can be an isothiazolinone-based biocide such as Kordek MLX™ (DuPont, Wilmington, DE). In certain embodiments, the biocide is 5-chloro-2-methyl-4-isothiazolin-3-one, 2-methyl-4-isothiazolin-3-one, benzisothiazolinone, 1,2-benzisothiazol-3[2H]-one, methylisothiazolinone, methylchloroisothiazolinone, or a combination thereof. The biocide can be present in the polishing composition at a concentration of about 1 ppm to about 750 ppm, preferably about 10 ppm to about 200 ppm. In some embodiments, the biocide is benzisothiazolinone.

The chemical-mechanical polishing composition comprises water. The water can be any suitable water including, for example, deionized water or distilled water. In some embodiments, the chemical-mechanical polishing composition can further comprise one or more organic solvents in combination with the water. For example, the polishing composition can further comprise a hydroxylic solvent such as methanol or ethanol, a ketonic solvent, an amide solvent, a sulfoxide solvent, and the like. In certain embodiments, the chemical-mechanical polishing composition comprises pure water.

The chemical-mechanical polishing composition can have any suitable conductivity. Accordingly, the polishing composition can have a conductivity of about 50 μS/cm or more, for example, about 75 μS/cm or more, about 100 μS/cm or more, about 150 μS/cm or more, or about 200 μS/cm or more. Alternatively, or in addition, the polishing composition can have a conductivity of about 1000 μS/cm or less, for example, about 900 μS/cm or less, about 800 μS/cm or less, about 700 μS/cm or less, about 600 μS/cm or less, about 500 μS/cm or less, about 400 μS/cm or less, about 300 μS/cm or less, or about 200 μS/cm or less. Thus, the polishing composition can have a conductivity bounded by any two of the aforementioned endpoints.

For example, the polishing composition can have a conductivity of about 50 μS/cm to about 1000 μS/cm, about 50 μS/cm to about 900 μS/cm, about 50 μS/cm to about 800 μS/cm, about 50 μS/cm to about 700 μS/cm, about 50 μS/cm to about 600 μS/cm, about 50 μS/cm to about 500 μS/cm, about 50 μS/cm to about 400 μS/cm, about 50 μS/cm to about 300 μS/cm, about 50 μS/cm to about 200 μS/cm, about 75 μS/cm to about 1000 μS/cm, about 75 μS/cm to about 900 μS/cm, about 75 μS/cm to about 800 μS/cm, about 75 μS/cm to about 700 μS/cm, about 75 μS/cm to about 600 μS/cm, about 75 μS/cm to about 500 μS/cm, about 75 μS/cm to about 400 μS/cm, about 75 μS/cm to about 300 μS/cm, about 75 μS/cm to about 200 μS/cm, about 100 μS/cm to about 1000 μS/cm, about 100 μS/cm to about 900 μS/cm, about 100 μS/cm to about 800 μS/cm, about 100 μS/cm to about 700 μS/cm, about 100 μS/cm to about 600 μS/cm, about 100 μS/cm to about 500 μS/cm, about 100 μS/cm to about 400 μS/cm, about 100 μS/cm to about 300 μS/cm, about 100 μS/cm to about 200 μS/cm, about 150 μS/cm to about 1000 μS/cm, about 150 μS/cm to about 900 μS/cm, about 150 μS/cm to about 800 μS/cm, about 150 μS/cm to about 700 μS/cm, about 150 μS/cm to about 600 μS/cm, about 150 μS/cm to about 500 μS/cm, about 150 μS/cm to about 400 μS/cm, about 150 μS/cm to about 300 μS/cm, about 200 μS/cm to about 1000 μS/cm, about 200 μS/cm to about 900 μS/cm, about 200 μS/cm to about 800 μS/cm, about 200 μS/cm to about 700 μS/cm, about 200 μS/cm to about 600 μS/cm, about 200 μS/cm to about 500 μS/cm, about 200 μS/cm to about 400 μS/cm, or about 200 μS/cm to about 300 μS/cm. In some embodiments, the polishing composition has a conductivity of about 100 μS/cm to about 400 μS/cm. In certain embodiments, the polishing composition has a conductivity of about 100 μS/cm to about 300 μS/cm.

In some embodiments, the polishing composition is colloidally stable at room temperature (i.e., 23° C.) for at least about 4 weeks (e.g., at least about 6 weeks, at least about 8 weeks, or at least about 12 weeks). In some embodiments, the polishing composition is colloidally stable at 45° C. for at least about 4 weeks (e.g., at least about 6 weeks, at least about 8 weeks, or at least about 12 weeks). In some embodiments, the polishing composition is colloidally stable at 60° C. for at least about 4 weeks (e.g., at least about 6 weeks, at least about 8 weeks, or at least about 12 weeks). In certain embodiments, the polishing composition is colloidally stable at 23° C., 45° C., or 60° C. for at least about 8 weeks.

In some embodiments, the chemical-mechanical polishing composition comprises (a) silica abrasive particles comprising an aminosilane compound, a phosphonium silane compound, or a combination thereof incorporated (i) on an outer surface thereof and/or (ii) internal to an outer surface thereof, (b) ceria abrasive particles, (c) one or more nitrogen-containing zwitterionic compounds, and (d) water.

In some embodiments, the chemical-mechanical polishing composition comprises (a) silica abrasive particles comprising an aminosilane compound, a phosphonium silane compound, or a combination thereof incorporated (i) on an outer surface thereof and/or (ii) internal to an outer surface thereof, (b) ceria abrasive particles, (c) one or more nitrogen-containing zwitterionic compounds, (d) a biocide, and (e) water.

In some embodiments, the chemical-mechanical polishing composition comprises (a) silica abrasive particles comprising an aminosilane compound, a phosphonium silane compound, or a combination thereof incorporated (i) on an outer surface thereof and/or (ii) internal to an outer surface thereof, (b) ceria abrasive particles, (c) picolinic acid, and (d) water.

In some embodiments, the chemical-mechanical polishing composition comprises (a) silica abrasive particles comprising an aminosilane compound, a phosphonium silane compound, or a combination thereof incorporated (i) on an outer surface thereof and/or (ii) internal to an outer surface thereof, (b) ceria abrasive particles, (c) picolinic acid, (d) a biocide, and (e) water.

The chemical-mechanical polishing composition can be produced by any suitable technique, many of which are known to those skilled in the art. The polishing composition can be prepared in a batch or continuous process. Generally, the polishing composition is prepared by combining the components of the polishing composition in any order. The term “component” as used herein includes individual ingredients (e.g., silica abrasive, ceria abrasive, optional nitrogen-containing zwitterionic compound, and/or any other optional additive, etc.) as well as any combination of ingredients (e.g., silica abrasive, ceria abrasive, optional nitrogen-containing zwitterionic compound, and/or any other optional additive, etc.).

For example, the polishing composition can be prepared by (i) providing all or a portion of the liquid carrier, (ii) dispersing the silica abrasive, ceria abrasive, optional nitrogen-containing zwitterionic compound, and/or any other optional additive, etc., using any suitable means for preparing such a dispersion, (iii) adjusting the pH of the dispersion as appropriate, and (iv) optionally adding suitable amounts of any other optional components and/or additives to the mixture.

Alternatively, the polishing composition can be prepared by (i) providing one or more components (e.g., ceria abrasive, optional nitrogen-containing zwitterionic compound, and/or any other optional additive, etc.) in a silica abrasive slurry, (ii) providing one or more components (e.g., ceria abrasive, optional nitrogen-containing zwitterionic compound, and/or any other optional additive, etc.) in an additive solution, (iii) combining the silica abrasive slurry and the additive solution to form a mixture, (iv) optionally adding suitable amounts of any other optional additives to the mixture, and (v) adjusting the pH of the mixture as appropriate.

Alternatively, the polishing composition can be prepared by (i) providing one or more components (e.g., silica abrasive, optional nitrogen-containing zwitterionic compound, and/or any other optional additive, etc.) in a ceria abrasive slurry, (ii) providing one or more components (e.g., silica abrasive, optional nitrogen-containing zwitterionic compound, and/or any other optional additive, etc.) in an additive solution, (iii) combining the ceria abrasive slurry and the additive solution to form a mixture, (iv) optionally adding suitable amounts of any other optional additives to the mixture, and (v) adjusting the pH of the mixture as appropriate.

The polishing composition can be supplied as a one-package system comprising a silica abrasive, ceria abrasive, optional nitrogen-containing zwitterionic compound, and/or any other optional additive, and water. Alternatively, the polishing composition of the invention can be supplied as a two-package system comprising (i) a silica abrasive slurry in a first package and an additive solution in a second package, wherein the silica abrasive slurry consists essentially of, or consists of, a silica abrasive, and water, and wherein the additive solution consists essentially of, or consists of, a ceria abrasive, optional nitrogen-containing zwitterionic compound, and/or any other optional additive or (ii) a ceria abrasive slurry in a first package and an additive solution in a second package, wherein the ceria abrasive slurry consists essentially of, or consists of, a ceria abrasive, and water, and wherein the additive solution consists essentially of, or consists of, a silica abrasive, optional nitrogen-containing zwitterionic compound, and/or any other optional additive. The two-package system allows for the adjustment of polishing composition characteristics by changing the blending ratio of the two packages, i.e., the silica abrasive slurry or the ceria abrasive slurry, and the additive solution.

Various methods can be employed to utilize such a two-package polishing system. For example, the silica abrasive slurry or the ceria abrasive slurry, and additive solution can be delivered to the polishing table by different pipes that are joined and connected at the outlet of supply piping. The silica abrasive slurry or the ceria abrasive slurry, and additive solution can be mixed shortly or immediately before polishing, or can be supplied simultaneously on the polishing table. Furthermore, when mixing the two packages, deionized water can be added, as desired, to adjust the polishing composition and resulting substrate polishing characteristics.

Similarly, a three-, four-, or more package system can be utilized in connection with the invention, wherein each of multiple containers contains different components of the inventive chemical-mechanical polishing composition, one or more optional components, and/or one or more of the same components in different concentrations.

In order to mix components contained in two or more storage devices to produce the polishing composition at or near the point-of-use, the storage devices typically are provided with one or more flow lines leading from each storage device to the point-of-use of the polishing composition (e.g., the platen, the polishing pad, or the substrate surface). As utilized herein, the term “point-of-use” refers to the point at which the polishing composition is applied to the substrate surface (e.g., the polishing pad or the substrate surface itself). By the term “flow line” is meant a path of flow from an individual storage container to the point-of-use of the component stored therein. The flow lines can each lead directly to the point-of-use, or two or more of the flow lines can be combined at any point into a single flow line that leads to the point-of-use. Furthermore, any of the flow lines (e.g., the individual flow lines or a combined flow line) can first lead to one or more other devices (e.g., pumping device, measuring device, mixing device, etc.) prior to reaching the point-of-use of the component(s).

The components of the polishing composition can be delivered to the point-of-use independently (e.g., the components are delivered to the substrate surface whereupon the components are mixed during the polishing process), or one or more of the components can be combined before delivery to the point-of-use, e.g., shortly or immediately before delivery to the point-of-use. Components are combined “immediately before delivery to the point-of-use” if the components are combined about 5 minutes or less prior to being added in mixed form onto the platen, for example, about 4 minutes or less, about 3 minutes or less, about 2 minutes or less, about 1 minute or less, about 45 seconds or less, about 30 seconds or less, about 10 seconds or less prior to being added in mixed form onto the platen, or simultaneously to the delivery of the components at the point-of-use (e.g., the components are combined at a dispenser). Components also are combined “immediately before delivery to the point-of-use” if the components are combined within 5 m of the point-of-use, such as within 1 m of the point-of-use or even within 10 cm of the point-of-use (e.g., within 1 cm of the point-of-use).

When two or more of the components of the polishing composition are combined prior to reaching the point-of-use, the components can be combined in the flow line and delivered to the point-of-use without the use of a mixing device. Alternatively, one or more of the flow lines can lead into a mixing device to facilitate the combination of two or more of the components. Any suitable mixing device can be used. For example, the mixing device can be a nozzle or jet (e.g., a high pressure nozzle or jet) through which two or more of the components flow. Alternatively, the mixing device can be a container-type mixing device comprising one or more inlets by which two or more components of the polishing slurry are introduced to the mixer, and at least one outlet through which the mixed components exit the mixer to be delivered to the point-of-use, either directly or via other elements of the apparatus (e.g., via one or more flow lines). Furthermore, the mixing device can comprise more than one chamber, each chamber having at least one inlet and at least one outlet, wherein two or more components are combined in each chamber. If a container-type mixing device is used, the mixing device preferably comprises a mixing mechanism to further facilitate the combination of the components. Mixing mechanisms are generally known in the art and include stirrers, blenders, agitators, paddled baffles, gas sparger systems, vibrators, etc.

The polishing composition also can be provided as a concentrate which is intended to be diluted with an appropriate amount of water prior to use. In such an embodiment, the polishing composition concentrate comprises the components of the polishing composition in amounts such that, upon dilution of the concentrate with an appropriate amount of water, each component of the polishing composition will be present in the polishing composition in an amount within the appropriate range recited above for each component. For example, the silica abrasive, ceria abrasive, optional nitrogen-containing zwitterionic compound, and/or any other optional additive can each be present in the concentrate in an amount that is about 2 times (e.g., about 3 times, about 4 times, or about 5 times) greater than the concentration recited above for each component so that, when the concentrate is diluted with an equal volume of water (e.g., 2 equal volumes water, 3 equal volumes of water, or 4 equal volumes of water, respectively), each component will be present in the polishing composition in an amount within the ranges set forth above for each component.

The invention further provides a method of chemically-mechanically polishing a substrate comprising: (i) providing a substrate, (ii) providing a polishing pad, (iii) providing a chemical-mechanical polishing composition comprising: (a) silica abrasive particles comprising an aminosilane compound, a phosphonium silane compound, or a combination thereof incorporated (i) on an outer surface thereof and/or (ii) internal to an outer surface thereof, (b) ceria abrasive particles, and (c) water, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the method of chemically-mechanically polishing a substrate comprises (i) providing a substrate, (ii) providing a polishing pad, (iii) providing a chemical-mechanical polishing composition comprising: (a) silica abrasive particles comprising an aminosilane compound, a phosphonium silane compound, or a combination thereof incorporated (i) on an outer surface thereof and/or (ii) internal to an outer surface thereof, (b) ceria abrasive particles, (c) one or more nitrogen-containing zwitterionic compounds, and (d) water, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the method of chemically-mechanically polishing a substrate comprises (i) providing a substrate, (ii) providing a polishing pad, (iii) providing a chemical-mechanical polishing composition comprising: (a) silica abrasive particles comprising an aminosilane compound, a phosphonium silane compound, or a combination thereof incorporated (i) on an outer surface thereof and/or (ii) internal to an outer surface thereof, (b) ceria abrasive particles, (c) one or more nitrogen-containing zwitterionic compounds, (d) a biocide, and (e) water, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the method of chemically-mechanically polishing a substrate comprises (i) providing a substrate, (ii) providing a polishing pad, (iii) providing a chemical-mechanical polishing composition comprising: (a) silica abrasive particles comprising an aminosilane compound, a phosphonium silane compound, or a combination thereof incorporated (i) on an outer surface thereof and/or (ii) internal to an outer surface thereof, (b) ceria abrasive particles, (c) picolinic acid, and (d) water, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the method of chemically-mechanically polishing a substrate comprises (i) providing a substrate, (ii) providing a polishing pad, (iii) providing a chemical-mechanical polishing composition comprising: (a) silica abrasive particles comprising an aminosilane compound, a phosphonium silane compound, or a combination thereof incorporated (i) on an outer surface thereof and/or (ii) internal to an outer surface thereof, (b) ceria abrasive particles, (c) picolinic acid, (d) a biocide, and (e) water, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

The chemical-mechanical polishing composition can be used to polish any suitable substrate and is especially useful for polishing substrates comprising at least one layer (typically a surface layer) comprised of silicon oxide, silicon nitride, polysilicon, or amorphous silicon. Suitable substrates include wafers used in the semiconductor industry. The wafers typically comprise or consist of, for example, a metal, metal oxide, metal nitride, metal composite, metal alloy, a low dielectric material, or combinations thereof. The method of the invention is particularly useful for polishing substrates comprising silicon oxide, silicon nitride, polysilicon, and/or amorphous silicon, i.e., polishing substrates comprising any one, two, three, or four of silicon oxide, silicon nitride, polysilicon, and/or amorphous silicon. In some embodiments, the polishing substrate comprises silicon nitride, polysilicon, and/or amorphous silicon in combination with silicon oxide.

In some embodiments, the substrate comprises silicon oxide on a surface of the substrate, and at least a portion of the silicon oxide on a surface of the substrate is abraded at a silicon oxide removal rate (Å/min) to polish the substrate. The silicon oxide can be any suitable silicon oxide, many forms of which are known in the art. Suitable types of silicon oxide include, but are not limited to, silicon oxide films derived from tetraethyl orthosilicate (TEOS), borophosphosilicate glass (BPSG), plasma enhanced tetraethyl orthosilicate (PETEOS), thermal oxide, undoped silicate glass, and high-density plasma (HDP) oxide. The chemical-mechanical polishing composition of the invention desirably exhibits a high removal rate when polishing a substrate comprising silicon oxide according to a method of the invention. For example, when polishing substrates comprising silicon oxide in accordance with an embodiment of the invention, the polishing composition desirably exhibits a removal rate of the silicon oxide of about 400 Å/min or higher, for example, about 500 Å/min or higher, about 600 Å/min or higher, about 700 Å/min or higher, about 800 Å/min or higher, about 900 Å/min or higher, about 1,000 Å/min or higher, about 1,100 Å/min or higher, about 1,200 Å/min or higher, about 1,500 Å/min or higher, about 2,000 Å/min or higher, about 3,000 Å/min or higher, or about 4,000 Å/min or higher.

In some embodiments, the substrate comprises silicon oxide and silicon nitride. The silicon nitride can be any suitable silicon nitride and can be applied to the surface by any suitable method (e.g., low pressure chemical vapor deposition (LPCVD) or plasma enhanced chemical vapor deposition (PECVD)). In certain embodiments, the substrate comprises silicon nitride on a surface of the substrate, and no silicon nitride on a surface of the substrate is abraded. In other embodiments, the substrate comprises silicon nitride on a surface of the substrate, and at least a portion of the silicon nitride on a surface of the substrate is abraded at a silicon nitride removal rate (Å/min) to polish the substrate.

The chemical-mechanical polishing composition of the invention desirably exhibits a low removal rate when polishing a substrate comprising silicon nitride according to a method of the invention. For example, when polishing substrates comprising silicon nitride in accordance with an embodiment of the invention, the polishing composition desirably exhibits a removal rate of the silicon nitride of about 200 Å/min or lower, for example, about 150 Å/min or lower, about 100 Å/min or lower, about 90 Å/min or lower, about 80 Å/min or lower, about 70 Å/min or lower, about 60 Å/min or lower, about 50 Å/min or lower, about 40 Å/min or lower, or about 30 Å/min or lower.

Thus, when used to polish a substrate comprising a silicon oxide layer and a silicon nitride layer, the polishing composition desirably exhibits selectivity for the polishing of the silicon oxide layer over the silicon nitride layer. In other words, the silicon oxide removal rate (Å/min) is greater than the silicon nitride removal rate (Å/min). When desirable, the chemical-mechanical polishing composition of the invention can be used to polish a substrate with a silicon oxide to silicon nitride polishing selectivity of about 5:1 or higher (e.g., about 10:1 or higher, about 15:1 or higher, about 25:1 or higher, about 50:1 or higher, about 100:1 or higher, or about 150:1 or higher). In some embodiments, the silicon oxide removal rate (Å/min) is at least 10 times greater (e.g., 10 to 200 times greater, 10 to 100 times greater, or 10 to 50 times greater) than the silicon nitride removal rate (Å/min). In some embodiments, the silicon oxide removal rate (Å/min) is at least 20 times greater (e.g., 20 to 200 times greater, 20 to 100 times greater, or 20 to 50 times greater) than the silicon nitride removal rate (Å/min). In certain embodiments, the silicon oxide removal rate (Å/min) is at least 30 times greater (e.g., 30 to 200 times greater, 30 to 100 times greater, or 30 to 50 times greater) than the silicon nitride removal rate (Å/min).

In some embodiments, the substrate comprises silicon oxide and polysilicon. The polysilicon can have any suitable phase, and can be amorphous, crystalline, or a combination thereof. In certain embodiments, the substrate comprises polysilicon on a surface of the substrate, and no polysilicon on a surface of the substrate is abraded. In other embodiments, the substrate comprises polysilicon on a surface of the substrate, and at least a portion of the polysilicon on a surface of the substrate is abraded at a polysilicon removal rate (Å/min) to polish the substrate.

In some embodiments, the chemical-mechanical polishing composition of the invention desirably exhibits a low removal rate when polishing a substrate comprising polysilicon according to a method of the invention. For example, when polishing substrates comprising polysilicon in accordance with an embodiment of the invention, the polishing composition desirably exhibits a removal rate of the polysilicon of about 500 Å/min or lower, for example, about 400 Å/min or lower, about 250 Å/min or lower, about 100 Å/min or lower, or about 50 Å/min or lower. In other embodiments, the chemical-mechanical polishing composition of the invention desirably exhibits a high removal rate when polishing a substrate comprising polysilicon according to a method of the invention. For example, when polishing substrates comprising polysilicon in accordance with an embodiment of the invention, the polishing composition desirably exhibits a removal rate of the polysilicon of about 500 Å/min or higher, for example, about 600 Å/min or higher, about 700 Å/min or higher, about 800 Å/min or higher, about 900 Å/min or higher, or 1000 Å/min or lower.

In some embodiments, when used to polish a substrate comprising a silicon oxide layer and a polysilicon layer, the polishing composition desirably exhibits selectivity for the polishing of the silicon oxide layer over the polysilicon layer. In other words, the silicon oxide removal rate (Å/min) is greater than the polysilicon removal rate (Å/min). When desirable, the chemical-mechanical polishing composition of the invention can be used to polish a substrate with a silicon oxide to polysilicon polishing selectivity of about 2:1 or higher (e.g., about 3:1 or higher, about 4:1 or higher, about 5:1 or higher, about 10:1 or higher, or about 20:1 or higher). In some embodiments, the silicon oxide removal rate (Å/min) is at least 3 times greater (e.g., 3 to 50 times greater, 3 to 20 times greater, or 3 to 10 times greater) than the polysilicon removal rate (Å/min). In some embodiments, the silicon oxide removal rate (Å/min) is at least 5 times greater (e.g., 5 to 50 times greater, 5 to 20 times greater, or 5 to 10 times greater) than the polysilicon removal rate (Å/min). In some embodiments, the silicon oxide removal rate (Å/min) is at least 10 times greater (e.g., 10 to 200 times greater, 10 to 100 times greater, or 10 to 50 times greater) than the polysilicon removal rate (Å/min).

In some embodiments, the substrate comprises silicon oxide and amorphous silicon. The amorphous silicon can be any suitable amorphous silicon, many forms of which are known in the art. In certain embodiments, the substrate comprises amorphous silicon on a surface of the substrate, and no amorphous silicon on a surface of the substrate is abraded. In other embodiments, the substrate comprises amorphous silicon on a surface of the substrate, and at least a portion of the amorphous silicon on a surface of the substrate is abraded at an amorphous silicon removal rate (Å/min) to polish the substrate.

In some embodiments, the chemical-mechanical polishing composition of the invention desirably exhibits a low removal rate when polishing a substrate comprising amorphous silicon according to a method of the invention. For example, when polishing substrates comprising amorphous silicon in accordance with an embodiment of the invention, the polishing composition desirably exhibits a removal rate of the amorphous silicon of about 500 Å/min or lower, for example, about 400 Å/min or lower, about 250 Å/min or lower, about 100 Å/min or lower, or about 50 Å/min or lower. In other embodiments, the chemical-mechanical polishing composition of the invention desirably exhibits a high removal rate when polishing a substrate comprising amorphous silicon according to a method of the invention. For example, when polishing substrates comprising amorphous silicon in accordance with an embodiment of the invention, the polishing composition desirably exhibits a removal rate of the amorphous silicon of about 500 Å/min or higher, for example, about 600 Å/min or higher, about 700 Å/min or higher, about 800 Å/min or higher, about 900 Å/min or higher, or 1000 Å/min or lower.

In some embodiments, when used to polish a substrate comprising a silicon oxide layer and an amorphous silicon layer, the polishing composition desirably exhibits selectivity for the polishing of the silicon oxide layer over the amorphous silicon layer. In other words, the silicon oxide removal rate (Å/min) is greater than the amorphous silicon removal rate (Å/min). When desirable, the chemical-mechanical polishing composition of the invention can be used to polish a substrate with a silicon oxide to amorphous silicon polishing selectivity of about 2:1 or higher (e.g., about 3:1 or higher, about 4:1 or higher, about 5:1 or higher, about 10:1 or higher, or about 20:1 or higher). In some embodiments, the silicon oxide removal rate (Å/min) is at least 3 times greater (e.g., 3 to 50 times greater, 3 to 20 times greater, or 3 to 10 times greater) than the amorphous silicon removal rate (Å/min). In some embodiments, the silicon oxide removal rate (Å/min) is at least 5 times greater (e.g., 5 to 50 times greater, 5 to 20 times greater, or 5 to 10 times greater) than the amorphous silicon removal rate (Å/min). In some embodiments, the silicon oxide removal rate (Å/min) is at least 10 times greater (e.g., 10 to 200 times greater, 10 to 100 times greater, or 10 to 50 times greater) than the amorphous silicon removal rate (Å/min).

In some embodiments, the polishing composition of the invention desirably exhibits low particle defects when polishing a substrate, as determined by suitable techniques. Particle defects on a substrate polished with the inventive polishing composition can be determined by any suitable technique. For example, laser light scattering techniques, such as dark field normal beam composite (DCN) and dark field oblique beam composite (DCO), can be used to determine particle defects on polished substrates. Suitable instrumentation for evaluating particle defectivity is available from, for example, KLA-Tencor (e.g., SURFSCAN™ SPI instruments operating at a 120 nm threshold or at 160 nm threshold).

The chemical-mechanical polishing composition and method of the invention are particularly suited for use in conjunction with a chemical-mechanical polishing apparatus. Typically, the apparatus comprises a platen, which, when in use, is in motion and has a velocity that results from orbital, linear, or circular motion, a polishing pad in contact with the platen and moving with the platen when in motion, and a carrier that holds a substrate to be polished by contacting and moving the substrate relative to the surface of the polishing pad. The polishing of the substrate takes place by the substrate being placed in contact with the polishing pad and the polishing composition of the invention, and then the polishing pad moving relative to the substrate, so as to abrade at least a portion of the substrate to polish the substrate.

A substrate can be polished with the chemical-mechanical polishing composition using any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, coformed products thereof, and mixtures thereof. Soft polyurethane polishing pads are particularly useful in conjunction with the inventive polishing method. Typical pads include but are not limited to SURFIN™ 000, SURFIN™ SSW1, SPM3100 Eminess Technologies), POLITEX™ commercially available from Dow Chemical Company (Newark, DE), and POLYPAS™ 27 commercially available from Fujibo (Osaka, JP), and EPIC™ D100 pads or NEXPLANAR™ E6088 commercially available from Cabot Microelectronics (Aurora, IL).

Desirably, the chemical-mechanical polishing apparatus further comprises an in situ polishing endpoint detection system, many of which are known in the art. Techniques for inspecting and monitoring the polishing process by analyzing light or other radiation reflected from a surface of the substrate being polished are known in the art. Such methods are described, for example, in U.S. Pat. Nos. 5,196,353, 5,433,651, 5,609,511. U.S. Pat. Nos. 5,643,046, 5,658,183, 5,730,642, 5,838,447, 5,872,633. U.S. Pat. Nos. 5,893,796, 5,949,927, and 5,964,643. Desirably, the inspection or monitoring of the progress of the polishing process with respect to a substrate being polished enables the determination of the polishing end-point, i.e., the determination of when to terminate the polishing process with respect to a particular substrate.

Aspects, including embodiments, of the invention described herein may be beneficial alone or in combination, with one or more other aspects or embodiments. Without limiting the foregoing description, certain non-limiting embodiments of the disclosure numbered 1-95 are provided below. As will be apparent to those of skill in the art upon reading this disclosure, each of the individually numbered embodiments may be used or combined with any of the preceding or following individually numbered embodiments. This is intended to provide support for all such combinations of embodiments and is not limited to combinations of embodiments explicitly provided below:

### EMBODIMENTS

(1) In embodiment (1) is presented a chemical-mechanical polishing composition comprising:
(a) silica abrasive particles comprising an aminosilane compound, a phosphonium silane compound, or a combination thereof incorporated (i) on an outer surface thereof and/or (ii) internal to an outer surface thereof,
(b) ceria abrasive particles, and
(c) water.

(2) In embodiment (2) is presented the polishing composition of embodiment (1), wherein the polishing composition has a pH of about 1 to about 7.

(3) In embodiment (3) is presented the polishing composition of embodiment (1) or embodiment (2), wherein the polishing composition has a pH of about 2 to about 6.

(4) In embodiment (4) is presented the polishing composition of any one of embodiments (1)-(3), wherein the polishing composition has a pH of about 3 to about 5.

(5) In embodiment (5) is presented the polishing composition of any one of embodiments (1)-(4), wherein the polishing composition comprises about 0.001 wt. % to about 10 wt. % of the silica abrasive particles.

(6) In embodiment (6) is presented the polishing composition of any one of embodiments (1)-(5), wherein the polishing composition comprises about 0.01 wt. % to about 1 wt. % of the silica abrasive particles.

(7) In embodiment (7) is presented the polishing composition of any one of embodiments (1)-(6), wherein the silica abrasive particles are colloidal silica particles.

(8) In embodiment (8) is presented the polishing composition of any one of embodiments (1)-(7), wherein the silica abrasive particles have a zeta potential of at least 13 mV.

(9) In embodiment (9) is presented the polishing composition of any one of embodiments (1)-(8), wherein the silica abrasive particles have a zeta potential of at least 20 mV.

(10) In embodiment (10) is presented the polishing composition of any one of embodiments (1)-(9), wherein the silica abrasive particles have a zeta potential of about 15 mV to about 35 mV.

(11) In embodiment (11) is presented the polishing composition of any one of embodiments (1)-(10), wherein the silica abrasive particles have an average particle size of about 30 nm to about 150 nm.

(12) In embodiment (12) is presented the polishing composition of any one of embodiments (1)-(11), wherein the silica abrasive particles have an average particle size of about 40 nm to about 100 nm.

(13) In embodiment (13) is presented the polishing composition of any one of embodiments (1)-(12), wherein the silica abrasive particles comprise an aminosilane compound, a phosphonium silane compound, or a combination thereof incorporated on an outer surface thereof.

(14) In embodiment (14) is presented the polishing composition of any one of embodiments (1)-(13), wherein the silica abrasive particles comprise an aminosilane compound, a phosphonium silane compound, or a combination thereof incorporated internal to an outer surface thereof.

(15) In embodiment (15) is presented the polishing composition of embodiment (14), wherein the silica abrasive particles have a core-shell structure wherein an outer shell is disposed over an inner core, and wherein the aminosilane compound and/or the phosphonium silane compound is incorporated within the outer shell.

(16) In embodiment (16) is presented the polishing composition of embodiment (15), wherein the outer shell has a thickness of at least 1 nm.

(17) In embodiment (17) is presented the polishing composition of any one of embodiments (1)-(16), wherein the silica abrasive particles comprise an aminosilane compound.

(18) In embodiment (18) is presented the polishing composition of embodiment (17), wherein the silica abrasive particles comprising the aminosilane compound have a molar ratio of the aminosilane compound to silica of less than 10%.

(19) In embodiment (19) is presented the polishing composition of embodiment (17) or embodiment (18), wherein the silica abrasive particles comprising the aminosilane compound have a molar ratio of the aminosilane compound to silica of less than 5%.

(20) In embodiment (20) is presented the polishing composition of any one of embodiments (1)-(19), wherein the silica abrasive particles further comprise an alkali catalyst incorporated internal to an outer surface thereof.

(21) In embodiment (21) is presented the polishing composition of embodiment (20), wherein the alkali catalyst has from 1 to 6 carbon atoms.

(22) In embodiment (22) is presented the polishing composition of embodiment (20) or embodiment (21), wherein the alkali catalyst is tetramethylammonium hydroxide or ethyloxypropylamine.

(23) In embodiment (23) is presented the polishing composition of any one of embodiments (1)-(22), wherein the aminosilane compound is selected from bis(2-hydroxyethyl)-3-aminopropyl trialkoxysilane, diethylaminomethyltrialkoxysilane, (N,N-diethyl-3-aminopropyl)trialkoxysilane, 3-(N-styrylmethyl-2-aminoethylamino)propyltrialkoxysilane, aminopropyl trialkoxysilane, N-(2-N-benzylaminoethyl)-3-aminopropyltrialkoxysilane, trialkoxysilyl propyl-N,N,N-trimethyl ammonium, N-(trialkoxysilylethyl)benzyl-N,N,N-trimethyl ammonium, (bis(methyldialkoxysilylpropyl)-N-methyl amine, bis(trialkoxysilylpropyl)urea, bis(3-(trialkoxysilyl)propyl)-ethylenediamine, bis(trialkoxysilylpropyl)amine, bis(trialkoxysilylpropyl)amine, 3-aminopropyltrialkoxysilane, N-(2-aminoethyl)-3-aminopropylmethyldialkoxysilane, N-(2-aminoethyl)-3-aminopropyltrialkoxysilane, 3-aminopropylmethyldialkoxysilane, 3-aminopropyltrialkoxysilane, (N-trialkoxysilylpropyl)polyethyleneimine, trialkoxysilylpropyldiethylenetriamine, N-phenyl-3-aminopropyltrialkoxysilane, N-(vinylbenzyl)-2-aminoethyl-3-aminopropyltrialkoxysilane, 4-aminobutyltrialkoxysilane, salts thereof, and mixtures thereof.

(24) In embodiment (24) is presented the polishing composition of any one of embodiments (1)-(23), wherein the polishing composition comprises about 0.001 wt. % to about 10 wt. % of the ceria abrasive particles.

(25) In embodiment (25) is presented the polishing composition of any one of embodiments (1)-(24), wherein the polishing composition comprises about 0.1 wt. % to about 5 wt. % of the ceria abrasive particles.

(26) In embodiment (26) is presented the polishing composition of any one of embodiments (1)-(25), wherein the ceria abrasive particles are colloidal ceria particles.

(27) In embodiment (27) is presented the polishing composition of any one of embodiments (1)-(26), wherein the ceria abrasive particles are calcined ceria particles, wet process-based ceria particles, fumed ceria particles, or a combination thereof.

(28) In embodiment (28) is presented the polishing composition of any one of embodiments (1)-(27), wherein the ceria abrasive particles are calcined ceria particles.

(29) In embodiment (29) is presented the polishing composition of any one of embodiments (1)-(28), wherein the ceria abrasive particles have an average particle size of about 50 nm to about 150 nm.

(30) In embodiment (30) is presented the polishing composition of any one of embodiments (1)-(29), wherein the silica abrasive particles and ceria abrasive particles have an aggregate zeta potential of about 20 mV to about 40 mV in the polishing composition.

(31) In embodiment (31) is presented the polishing composition of any one of embodiments (1)-(30), wherein the silica abrasive particles and ceria abrasive particles have an aggregate zeta potential of about 25 mV to about 35 mV in the polishing composition.

(32) In embodiment (32) is presented the polishing composition of any one of embodiments (1)-(31), wherein the silica abrasive particles and ceria abrasive particles have an aggregate average particle size of about 60 nm to about 110 nm in the polishing composition.

(33) In embodiment (33) is presented the polishing composition of any one of embodiments (1)-(32), wherein the silica abrasive particles and ceria abrasive particles have an aggregate average particle size of about 70 nm to about 100 nm in the polishing composition.

(34) In embodiment (34) is presented the polishing composition of any one of embodiments (1)-(33), wherein the polishing composition further comprises one or more nitrogen-containing zwitterionic compounds.

(35) In embodiment (35) is presented the polishing composition of embodiment (34), wherein the one or more nitrogen-containing zwitterionic compounds comprises picolinic acid.

(36) In embodiment (36) is presented the polishing composition of any one of embodiments (1)-(35), wherein the polishing composition further comprises a biocide.

(37) In embodiment (37) is presented the polishing composition of embodiment (36), wherein the biocide is benzisothiazolinone.

(38) In embodiment (38) is presented the polishing composition of any one of embodiments (1)-(37), wherein the polishing composition has a conductivity of about 100 μS/cm to about 400 μS/cm.

(39) In embodiment (39) is presented the polishing composition of any one of embodiments (1)-(38), wherein the polishing composition has a conductivity of about 100 μS/cm to about 300 μS/cm.

(40) In embodiment (40) is presented the polishing composition of any one of embodiments (1)-(39), wherein the polishing composition is colloidally stable for at least 8 weeks.

(41) In embodiment (41) is presented a method of chemically-mechanically polishing a substrate comprising:
(i) providing a substrate,
(ii) providing a polishing pad,
(iii) providing a chemical-mechanical polishing composition comprising:
   (a) silica abrasive particles comprising an aminosilane compound, a phosphonium silane compound, or a combination thereof incorporated (i) on an outer surface thereof and/or (ii) internal to an outer surface thereof,
   (b) ceria abrasive particles, and
   (c) water,
(iv) contacting the substrate with the polishing pad and the chemical-mechanical polishing composition, and
(v) moving the polishing pad and the chemical-mechanical polishing composition relative to the substrate to abrade at least a portion of the substrate to polish the substrate.

(42) In embodiment (42) is presented the method of embodiment (41), wherein the polishing composition has a pH of about 1 to about 7.

(43) In embodiment (43) is presented the method of embodiment (41) or embodiment (42), wherein the polishing composition has a pH of about 2 to about 6.

(44) In embodiment (44) is presented the method of any one of embodiments (41)-(43), wherein the polishing composition has a pH of about 3 to about 5.

(45) In embodiment (45) is presented the method of any one of embodiments (41)-(44), wherein the polishing composition comprises about 0.001 wt. % to about 10 wt. % of the silica abrasive particles.

(46) In embodiment (46) is presented the method of any one of embodiments (41)-(45), wherein the polishing composition comprises about 0.01 wt. % to about 1 wt. % of the silica abrasive particles.

(47) In embodiment (47) is presented the method of any one of embodiments (41)-(46), wherein the silica abrasive particles are colloidal silica particles.

(48) In embodiment (48) is presented the method of any one of embodiments (41)-(47), wherein the silica abrasive particles have a zeta potential of at least 13 mV.

(49) In embodiment (49) is presented the method of any one of embodiments (41)-(48), wherein the silica abrasive particles have a zeta potential of at least 20 mV.

(50) In embodiment (50) is presented the method of any one of embodiments (41)-(49), wherein the silica abrasive particles have a zeta potential of about 15 mV to about 35 mV.

(51) In embodiment (51) is presented the method of any one of embodiments (41)-(50), wherein the silica abrasive particles have an average particle size of about 30 nm to about 150 nm.

(52) In embodiment (52) is presented the method of any one of embodiments (41)-(51), wherein the silica abrasive particles have an average particle size of about 40 nm to about 100 nm.

(53) In embodiment (53) is presented the method of any one of embodiments (41)-(52), wherein the silica abrasive particles comprise an aminosilane compound, a phosphonium silane compound, or a combination thereof incorporated on an outer surface thereof.

(54) In embodiment (54) is presented the method of any one of embodiments (41)-(53), wherein the silica abrasive particles comprise an aminosilane compound, a phosphonium silane compound, or a combination thereof incorporated internal to an outer surface thereof.

(55) In embodiment (55) is presented the method of embodiment (54), wherein the silica abrasive particles have a core-shell structure wherein an outer shell is disposed over an inner core, and wherein the aminosilane compound and/or the phosphonium silane compound is incorporated within the outer shell.

(56) In embodiment (56) is presented the method of embodiment (55), wherein the outer shell has a thickness of at least 1 nm.

(57) In embodiment (57) is presented the method of any one of embodiments (41)-(56), wherein the silica abrasive particles comprise an aminosilane compound.

(58) In embodiment (58) is presented the method of embodiment (57), wherein the silica abrasive particles comprising the aminosilane compound have a molar ratio of the aminosilane compound to silica of less than 10%.

(59) In embodiment (59) is presented the method of embodiment (57) or embodiment (58), wherein the silica abrasive particles comprising the aminosilane compound have a molar ratio of the aminosilane compound to silica of less than 5%.

(60) In embodiment (60) is presented the method of any one of embodiments (41)-(59), wherein the silica abrasive particles further comprise an alkali catalyst incorporated internal to an outer surface thereof

(61) In embodiment (61) is presented the method of embodiment (60), wherein the alkali catalyst has from 1 to 6 carbon atoms.

(62) In embodiment (62) is presented the method of embodiment (60) or embodiment (61), wherein the alkali catalyst is tetramethylammonium hydroxide or ethyloxypropylamine.

(63) In embodiment (63) is presented the method of any one of embodiments (41)-(62), wherein the aminosilane compound is selected from bis(2-hydroxyethyl)-3-aminopropyl trialkoxysilane, diethylaminomethyltrialkoxysilane, (N,N-diethyl-3-aminopropyl)trialkoxysilane, 3-(N-styrylmethyl-2-aminoethylamino)propyltrialkoxysilane, aminopropyl trialkoxysilane, N-(2-N-benzylaminoethyl)-3-aminopropyltrialkoxysilane, trialkoxysilyl propyl-N,N,N-trimethyl ammonium, N-(trialkoxysilylethyl)benzyl-N,N,N-trimethyl ammonium, (bis(methyldialkoxysilylpropyl)-N-methyl amine, bis(trialkoxysilylpropyl)urea, bis(3-(trialkoxysilyl)propyl)-ethylenediamine, bis(trialkoxysilylpropyl)amine, bis(trialkoxysilylpropyl)amine, 3-aminopropyltrialkoxysilane, N-(2-aminoethyl)-3-aminopropylmethyldialkoxysilane, N-(2-aminoethyl)-3-aminopropyltrialkoxysilane, 3-aminopropylmethyldialkoxysilane, 3-aminopropyltrialkoxysilane, (N-trialkoxysilylpropyl)polyethyleneimine, trialkoxysilylpropyldiethylenetriamine, N-phenyl-3-aminopropyltrialkoxysilane, N-(vinylbenzyl)-2-aminoethyl-3-aminopropyltrialkoxysilane, 4-aminobutyltrialkoxysilane, salts thereof, and mixtures thereof.

(64) In embodiment (64) is presented the method of any one of embodiments (41)-(63), wherein the polishing composition comprises about 0.001 wt. % to about 10 wt. % of the ceria abrasive particles.

(65) In embodiment (65) is presented the method of any one of embodiments (41)-(64), wherein the polishing composition comprises about 0.1 wt. % to about 5 wt. % of the ceria abrasive particles.

(66) In embodiment (66) is presented the method of any one of embodiments (41)-(65), wherein the ceria abrasive particles are colloidal ceria particles.

(67) In embodiment (67) is presented the method of any one of embodiments (41)-(66), wherein the ceria abrasive particles are calcined ceria particles, wet process-based ceria particles, fumed ceria particles, or a combination thereof.

(68) In embodiment (68) is presented the method of any one of embodiments (41)-(67), wherein the ceria abrasive particles are calcined ceria particles.

(69) In embodiment (69) is presented the method of any one of embodiments (41)-(68), wherein the ceria abrasive particles have an average particle size of about 50 nm to about 150 nm.

(70) In embodiment (70) is presented the method of any one of embodiments (41)-(69), wherein the silica abrasive particles and ceria abrasive particles have an aggregate zeta potential of about 20 mV to about 40 mV in the polishing composition.

(71) In embodiment (71) is presented the method of any one of embodiments (41)-(70), wherein the silica abrasive particles and ceria abrasive particles have an aggregate zeta potential of about 25 mV to about 35 mV in the polishing composition.

(72) In embodiment (72) is presented the method of any one of embodiments (41)-(71), wherein the silica abrasive particles and ceria abrasive particles have an aggregate average particle size of about 60 nm to about 110 nm in the polishing composition.

(73) In embodiment (73) is presented the method of any one of embodiments (41)-(72), wherein the silica abrasive particles and ceria abrasive particles have an aggregate average particle size of about 70 nm to about 100 nm in the polishing composition.

(74) In embodiment (74) is presented the method of any one of embodiments (41)-(73), wherein the polishing composition further comprises one or more nitrogen-containing zwitterionic compounds.

(75) In embodiment (75) is presented the method of embodiment (74), wherein the one or more nitrogen-containing zwitterionic compounds comprises picolinic acid.

(76) In embodiment (76) is presented the method of any one of embodiments (41)-(75), wherein the polishing composition further comprises a biocide.

(77) In embodiment (77) is presented the method of embodiment (76), wherein the biocide is benzisothiazolinone.

(78) In embodiment (78) is presented the method of any one of embodiments (41)-(77), wherein the polishing composition has a conductivity of about 100 μS/cm to about 400 μS/cm.

(79) In embodiment (79) is presented the method of any one of embodiments (41)-(78), wherein the polishing composition has a conductivity of about 100 μS/cm to about 300 μS/cm.

(80) In embodiment (80) is presented the method of any one of embodiments (41)-(79), wherein the polishing composition is colloidally stable for at least 8 weeks.

(81) In embodiment (81) is presented the method of any one of embodiments (41)-(80), wherein the substrate comprises silicon oxide on a surface of the substrate, and wherein at least a portion of the silicon oxide on a surface of the substrate is abraded at a silicon oxide removal rate (Å/min) to polish the substrate.

(82) In embodiment (82) is presented the method of embodiment (81), wherein the substrate further comprises silicon nitride on a surface of the substrate, and wherein no silicon nitride on the surface of the substrate is abraded.

(83) In embodiment (83) is presented the method of embodiment (81), wherein the substrate further comprises silicon nitride on a surface of the substrate, and wherein at least a portion of the silicon nitride on a surface of the substrate is abraded at a silicon nitride removal rate (Å/min) to polish the substrate.

(84) In embodiment (84) is presented the method of embodiment (83), wherein the silicon oxide removal rate (Å/min) is greater than the silicon nitride removal rate (Å/min).

(85) In embodiment (85) is presented the method of embodiment (84), wherein the silicon oxide removal rate (Å/min) is at least 10 times greater than the silicon nitride removal rate (Å/min).

(86) In embodiment (86) is presented the method of embodiment (85), wherein the silicon oxide removal rate (Å/min) is at least 20 times greater than the silicon nitride removal rate (Å/min).

(87) In embodiment (87) is presented the method of embodiment (86), wherein the silicon oxide removal rate (Å/min) is at least 30 times greater than the silicon nitride removal rate (Å/min).

(88) In embodiment (88) is presented the method of embodiment (81), wherein the substrate further comprises polysilicon on a surface of the substrate, and wherein no polysilicon on the surface of the substrate is abraded.

(89) In embodiment (89) is presented the method of embodiment (81), wherein the substrate further comprises polysilicon on a surface of the substrate, and wherein at least a portion of the polysilicon on a surface of the substrate is abraded at a polysilicon removal rate (Å/min) to polish the substrate.

(90) In embodiment (90) is presented the method of embodiment (89), wherein the silicon oxide removal rate (Å/min) is greater than the polysilicon removal rate (Å/min).

(91) In embodiment (91) is presented the method of embodiment (90), wherein the silicon oxide removal rate (Å/min) is at least 10 times greater than the polysilicon removal rate (Å/min).

(92) In embodiment (92) is presented the method of embodiment (81), wherein the substrate further comprises amorphous silicon on a surface of the substrate, and wherein no amorphous silicon on the surface of the substrate is abraded.

(93) In embodiment (93) is presented the method of embodiment (81), wherein the substrate further comprises amorphous silicon on a surface of the substrate, and wherein at least a portion of the amorphous silicon on a surface of the substrate is abraded at an amorphous silicon removal rate (Å/min) to polish the substrate.

(94) In embodiment (94) is presented the method of embodiment (93), wherein the silicon oxide removal rate (Å/min) is greater than the amorphous silicon removal rate (Å/min).

(95) In embodiment (95) is presented the method of embodiment (94), wherein the silicon oxide removal rate (Å/min) is at least 10 times greater than the amorphous silicon removal rate (Å/min).

### EXAMPLES

These following examples further illustrate the invention but, of course, should not be construed as in any way limiting its scope.

The following abbreviations are used throughout the Examples: removal rate (RR); approximate average particle size (D_{W}); tetraethyl orthosilicate (TEOS); silicon nitride (SiN), polysilicon (Poly); and amorphous silicon (A-Si).

In the following examples, TEOS, SiN, Poly, or A-Si were coated on silicon, and the resulting patterned substrates were polished using a Logitech 2 benchtop polishing machine at 3 PSI (20.55 kPa) downforce using a NEXPLANAR™ E6088 commercially available from Cabot Microelectronics (Aurora, IL) conditioned with a product commercially identified as A82 (3M, St. Paul, MN). Logitech polishing parameters were as follows: head speed=93 rpm, platen speed=87 rpm, total flow rate=50 mL/min. Removal rates were calculated by measuring the film thickness, using spectroscopic elipsometry, and subtracting the final thickness from the initial thickness.

### Example 1

This example demonstrates the effect of ceria abrasive particles, silica abrasive particles comprising an aminosilane compound, a phosphonium silane compound, or a combination thereof, nitrogen-containing zwitterionic compound, and biocide on the polishing performance provided by a polishing composition prepared according to the invention.

Polishing Compositions 1A-1F, used in this example, were prepared by combining ceria abrasive particles and silica abrasive particles (Silica Abrasive A-silica abrasive particles comprising an aminosilane compound internal to an outer surface thereof with an average particle size of about 50 nm, a zeta potential of about 20 mV, and a molar ratio of the aminosilane compound to silica of approximately 10%) with picolinic acid and biocide, and the pH of each polishing composition was adjusted to 4. The resulting concentrate was diluted 10-fold to provide the amounts specified in Table 1.

TABLE 1
Polishing Compositions 1A-1F

| | Ceria Abrasive | Silica Abrasive | Picolinic | |
|---|---|---|---|---|
| | Particles | Particles | Acid | Biocide |
| | (wt. %) | (wt. %) | (ppm) | (ppm) |
| Polishing | calcined ceria | (0) | 333 | benzisothiazolinone |
| Composition | with D_{W} = 90 nm | | | (14) |
| 1A | (0.29) | | | |
| Polishing | calcined ceria | Silica | 333 | benzisothiazolinone |
| Composition | with D_{W} = 90 nm | Abrasive A | | (14) |
| 1B | (0.29) | (0.095) | | |
| Polishing | colloidal ceria | (0) | 333 | benzisothiazolinone |
| Composition | with D_{W} = 110-120 | | | (14) |
| 1C | nm (0.29) | | | |
| Polishing | colloidal ceria | Silica | 333 | benzisothiazolinone |
| Composition | with D_{W} = 110-120 | Abrasive A | | (14) |
| 1D | nm (0.29) | (0.095) | | |
| Polishing | colloidal ceria | Silica | 333 | 2-methyl-4- |
| Composition | with D_{W} = 110-120 | Abrasive A | | isothiazolin-3-one |
| 1E | nm (0.29) | (0.095) | | (14) |
| Polishing | colloidal ceria | Silica | 0 | benzisothiazolinone |
| Composition | with D_{W} = 110-120 | Abrasive A | | (14) |
| 1F | nm (0.29) | (0.095) | | |

Patterned substrates comprising TEOS, SiN (low pressure chemical vapor deposition (LPCVD)), Poly, or A-Si were each polished under identical conditions (i.e., 3 PSI (20.55 kPa) downforce, head speed=85 rpm, platen speed=100 rpm, and total flow rate=150 mL/min) with Polishing Compositions 1A-1F, as defined in Table 1. Following polishing, the RR for TEOS, SiN, Poly, or A-Si were determined, and the results are set forth in Table 2.

TABLE 2
Polishing Removal Rates of Polishing Compositions 1A-1F

| | TEOS | SiN | Poly | A-Si |
|---|---|---|---|---|
| | (Å/min) | (Å/min) | (Å/min) | (Å/min) |
| Polishing Composition 1A | 8284 | 8 | 852 | 248 |
| Polishing Composition 1B | 8119 | 4 | 785 | 1123 |
| Polishing Composition 1C | 4598 | 7 | 763 | 262 |
| Polishing Composition 1D | 3597 | 8 | 774 | 867 |
| Polishing Composition 1E | 3860 | 10 | 1308 | 1115 |
| Polishing Composition 1F | 3261 | 644 | 541 | 560 |

As is apparent from the results set forth in Table 2, Polishing Compositions 1B, 1D, 1E, and 1F, containing silica abrasive particles comprising an aminosilane compound, exhibited higher A-Si removal rates than Polishing Compositions 1A and 1C, which did not contain silica abrasive particles. These results show that the silica abrasive particles comprising an aminosilane compound increased A-Si removal rate.

In addition, Table 2 shows that Polishing Composition 1E, containing 2-methyl-4-isothiazolin-3-one, exhibited higher Poly removal rate and higher A-Si removal rate than Polishing Compositions 1D, which contained benzisothiazolinone. These results show that benzisothiazolinone provided higher selectivity for removal of TEOS relative to Poly and A-Si, when compared to 2-methyl-4-isothiazolin-3-one.

Table 2 also shows that Polishing Composition 1F, which did not contain picolinic acid, exhibited a significantly higher SiN removal rate than Polishing Compositions 1A-1E, containing picolinic acid. These results show that the presence of picolinic acid provided higher selectivity for removal of TEOS relative to SiN.

### Example 2

This example demonstrates the effect of ceria abrasive particle size on the polishing performance provided by a polishing composition prepared according to the invention.

Polishing Compositions 2A-2D, used in this example, were prepared by combining ceria abrasive particles and silica abrasive particles (Silica Abrasive A-silica abrasive particles comprising an aminosilane compound internal to an outer surface thereof with an average particle size of about 50 nm, a zeta potential of about 20 mV, and a molar ratio of the aminosilane compound to silica of approximately 10%) with picolinic acid (333 ppm) and benzisothiazolinone (14 ppm), and the pH of each polishing composition was adjusted to 4. The resulting concentrate was diluted 10-fold to provide the amounts specified in Table 3.

TABLE 3
Polishing Compositions 2A-2D

| | Ceria Abrasive Particles | Silica Abrasive Particles |
|---|---|---|
| | (wt. %) | (wt. %) |
| Polishing | colloidal ceria with | (0) |
| Composition 2A | D_{W} = 110-120 nm (0.29) | |
| Polishing | colloidal ceria with | Silica Abrasive A (0.095) |
| Composition 2B | D_{W} = 110-120 nm (0.29) | |
| Polishing | ceria with D_{W} = 80 nm | Silica Abrasive A (0.095) |
| Composition 2C | (0.29) | |
| Polishing | ceria with D_{W} = 20-25 nm | Silica Abrasive A (0.095) |
| Composition 2D | (0.29) | |

Patterned substrates comprising TEOS, SiN (low pressure chemical vapor deposition (LPCVD)), Poly, or A-Si were each polished under identical conditions (i.e., 3 PSI (20.55 kPa) downforce, head speed=85 rpm, platen speed=100 rpm, and total flow rate=150 mL/min) with Polishing Compositions 2A-2D, as defined in Table 3. Following polishing, the RR for TEOS, SiN, Poly, or A-Si were determined, and the results are set forth in Table 4.

TABLE 4
Polishing Removal Rates of Polishing Compositions 2A-2D

| | TEOS | SiN | Poly | A-Si |
|---|---|---|---|---|
| | (Å/min) | (Å/min) | (Å/min) | (Å/min) |
| Polishing Composition 2A | 4598 | 7 | 763 | 262 |
| Polishing Composition 2B | 3597 | 9 | 774 | 867 |
| Polishing Composition 2C | 1570 | — | 817 | 884 |
| Polishing Composition 2D | 914 | 12 | 1050 | 1123 |

As is apparent from the results set forth in Table 4, increasing the ceria abrasive particle size reduced the TEOS removal rate while maintaining high Poly removal rate and high A-Si removal rate. These results show that modifying the ceria abrasive particle size desirably provides tunability to the removal rate ratio and selectivity between TEOS, Poly, and A-Si without significantly affecting the SiN removal rate.

### Example 3

This example demonstrates the effect of silica abrasive particle size on the polishing performance provided by a polishing composition prepared according to the invention.

Polishing Compositions 3A-3C, used in this example, were prepared by combining ceria abrasive particles and silica abrasive particles comprising an aminosilane compound (Silica Abrasive A—silica abrasive particles comprising an aminosilane compound internal to an outer surface thereof with an average particle size of about 50 nm, a zeta potential of about 20 mV, and a molar ratio of the aminosilane compound to silica of approximately 10% or Silica Abrasive B—silica abrasive particles comprising an aminosilane compound on an outer surface thereof with an average particle size of about 120 nm, a zeta potential of about 40 mV, and a molar ratio of the aminosilane compound to silica of approximately 10%) with picolinic acid (333 ppm) and benzisothiazolinone (14 ppm), and the pH of each polishing composition was adjusted to 4. The resulting concentrate was diluted 10-fold to provide the amounts specified in Table 5. Silica Abrasive B had a larger average particle size than Silica Abrasive A.

TABLE 5
Polishing Compositions 3A-3C

| | Ceria Abrasive Particles | Silica Abrasive |
|---|---|---|
| | (wt. %) | Particles (wt. %) |
| Polishing | colloidal ceria with D_{W} = | (0) |
| Composition 3A | 110-120 nm (0.29) | |
| Polishing | colloidal ceria with D_{W} = | Silica Abrasive A |
| Composition 3B | 110-120 nm (0.29) | (0.095) |
| Polishing | colloidal ceria with D_{W} = | Silica Abrasive B |
| Composition 3C | 110-120 nm (0.29) | (0.095) |

Patterned substrates comprising TEOS, SiN (low pressure chemical vapor deposition (LPCVD)), Poly, or A-Si were each polished under identical conditions (i.e., 3 PSI (20.55 kPa) downforce, head speed=85 rpm, platen speed=100 rpm, and total flow rate=150 mL/min) with Polishing Compositions 3A-3C, as defined in Table 5. Following polishing, the RR for TEOS, SiN, Poly, or A-Si were determined, and the results are set forth in Table 6.

TABLE 6
Polishing Removal Rates of Polishing Compositions 3A-3C

| | TEOS | SiN | Poly | A-Si |
|---|---|---|---|---|
| | (Å/min) | (Å/min) | (Å/min) | (Å/min) |
| Polishing Composition 3A | 4598 | 7 | 763 | 262 |
| Polishing Composition 3B | 3597 | 9 | 774 | 867 |
| Polishing Composition 3C | 4340 | 8 | 753 | 787 |

As is apparent from the results set forth in Table 6, increasing the silica abrasive particle size increased the TEOS removal rate while maintaining high Poly removal rate and high A-Si removal rate. These results show that modifying the silica abrasive particle size desirably provides tunability to the removal rate ratio and selectivity between TEOS, Poly, and A-Si without significantly affecting the SiN removal rate.

### Example 4

This example provides an exemplary particle size analysis of a polishing composition comprising ceria abrasive particles and silica abrasive particles comprising an aminosilane compound, a phosphonium silane compound, or a combination thereof prepared according to the invention and demonstrates the stability of the polishing composition.

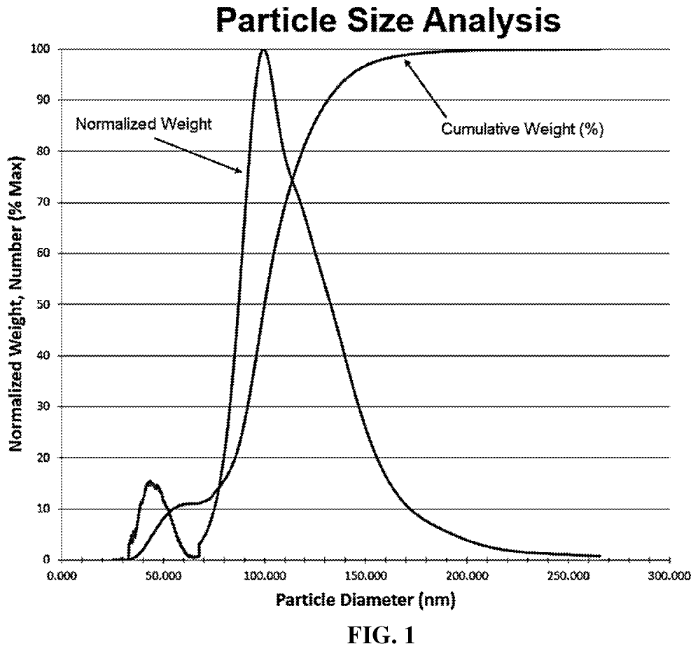

A polishing composition comprising 0.29 wt. % ceria abrasive particles and 0.095 wt. % silica abrasive particles (Silica Abrasive A-silica abrasive particles comprising an aminosilane compound internal to an outer surface thereof with an average particle size of about 50 nm, a zeta potential of about 20 mV, and a molar ratio of the aminosilane compound to silica of approximately 10%), picolinic acid (3330 ppm), and benzisothiazolinone (140 ppm) was aged for 4 weeks at room temperature (23° C.). The particle size distribution of the aged polishing composition was subjected to CPS particle size analysis and the results are set forth in FIG. 1.

As is apparent from the results set forth in FIG. 1, the polishing composition maintained two distinct peaks corresponding to the particle size of the ceria abrasive particles (left) and the silica abrasive particles comprising an aminosilane compound (right). These results show that the polishing composition comprising ceria abrasive particles and silica abrasive particles comprising an aminosilane compound was stable for a period of at least 4 weeks.

### Example 5

This example demonstrates the stability of a polishing composition comprising ceria abrasive particles and silica abrasive particles comprising an aminosilane compound, a phosphonium silane compound, or a combination thereof prepared according to the invention.

Polishing Compositions 5A-5E, used in this example, were prepared by combining 3 wt. % ceria abrasive particles and 1 wt. % silica abrasive particles comprising an aminosilane compound (Silica Abrasive A—silica abrasive particles comprising an aminosilane compound internal to an outer surface thereof with an average particle size of about 50 nm, a zeta potential of about 20 mV, and a molar ratio of the aminosilane compound to silica of approximately 10% or Silica Abrasive B—silica abrasive particles comprising an aminosilane compound on an outer surface thereof with an average particle size of about 120 nm, a zeta potential of about 40 mV, and a molar ratio of the aminosilane compound to silica of approximately 10%), picolinic acid (3330 ppm), and benzisothiazolinone (140 ppm) using the ceria abrasive particles and silica abrasive particles set forth in Table 7. Silica Abrasive B had a larger average particle size than Silica Abrasive A.

TABLE 7
Polishing Compositions 5A-5E

| | | Silica Abrasive |
|---|---|---|
| | Ceria Abrasive Particles | Particles |
| Polishing | colloidal ceria with D_{W} = | Silica Abrasive |
| Composition 5A | 110-120 nm (0.29) | A |
| Polishing | calcined ceria with D_{W} = | Silica Abrasive |
| Composition 5B | 90 nm (0.29) | A |
| Polishing | ceria with D_{W} = 80 nm (0.29) | Silica Abrasive |
| Composition 5C | | A |
| Polishing | colloidal ceria with D_{W} = | Silica Abrasive |
| Composition 5D | 110-120 nm (0.29) | B |
| Polishing | ceria with D_{W} = 20-25 nm | Silica Abrasive |
| Composition 5E | (0.29) | A |

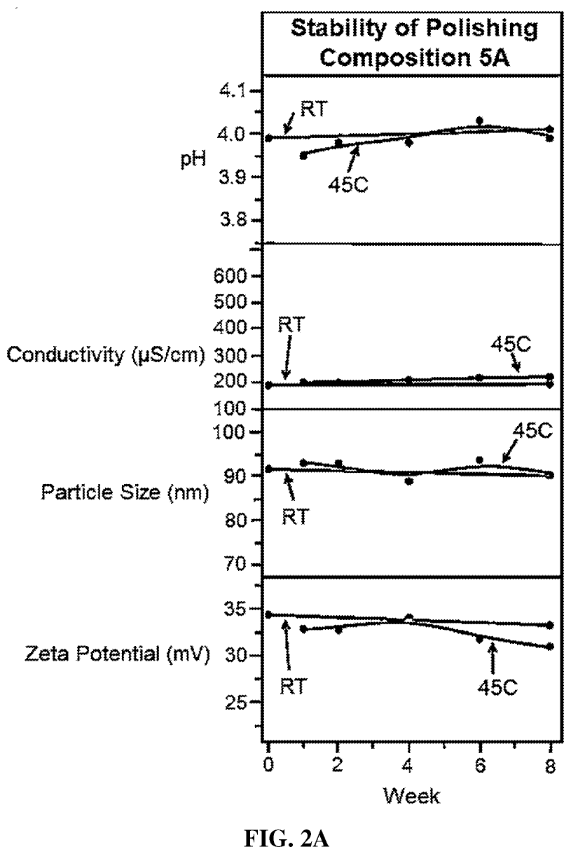

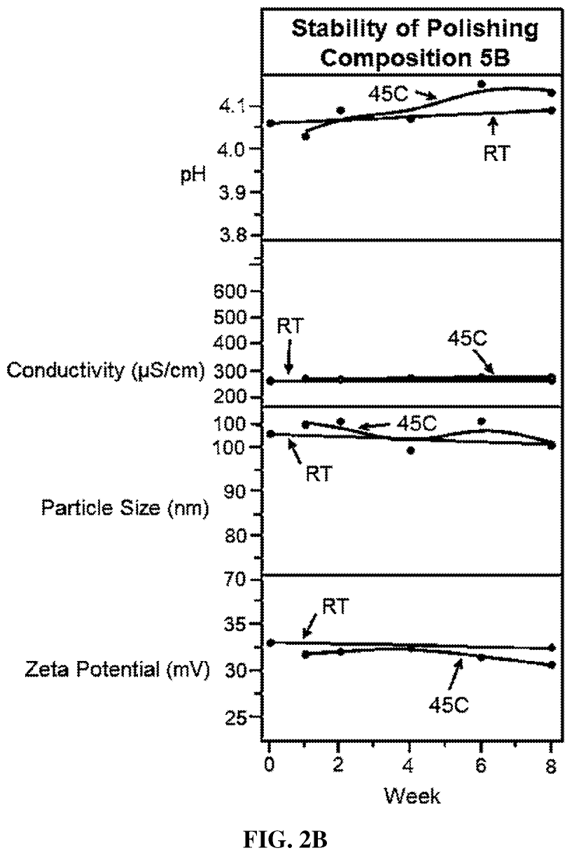

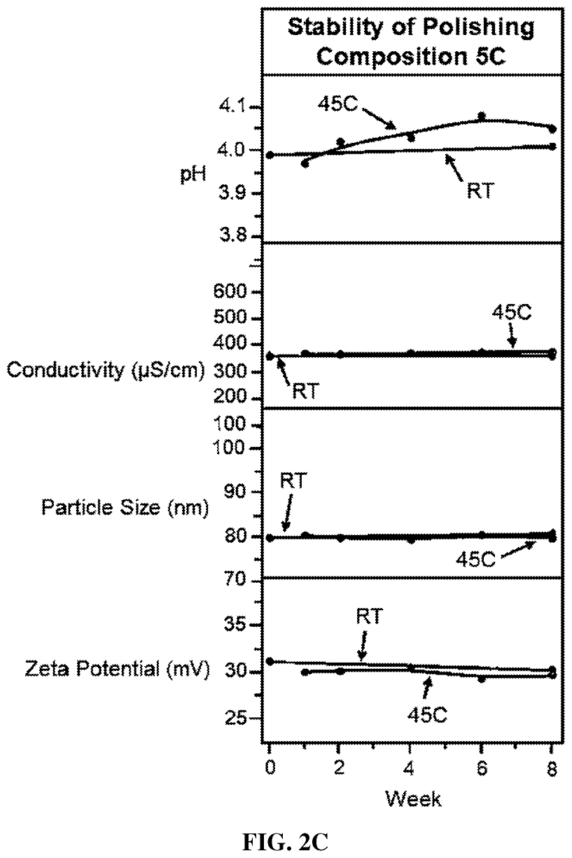

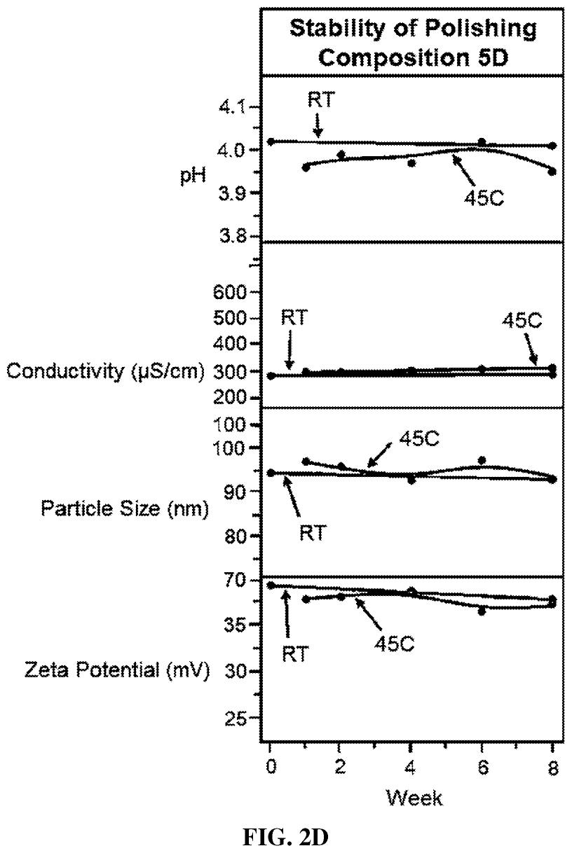

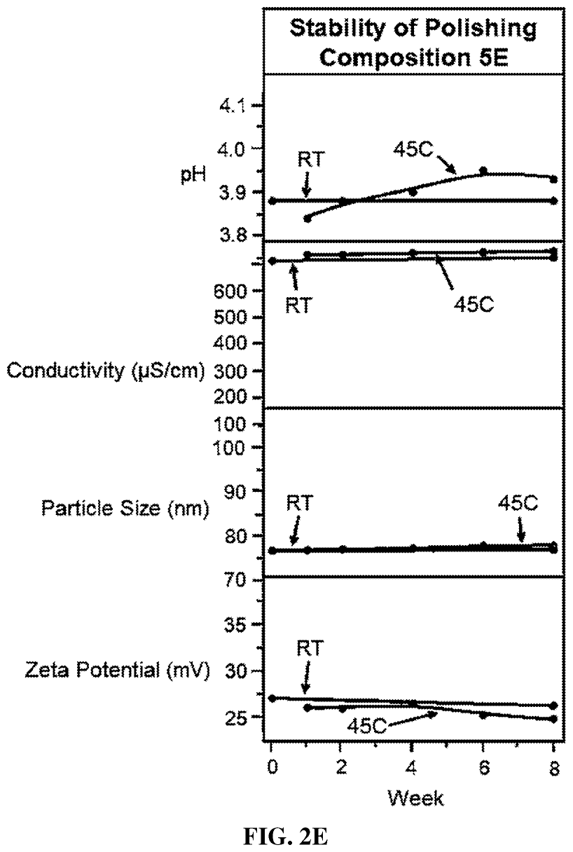

The resulting compositions were each aged for 8 weeks at room temperature (23° C.) or 8 weeks at 45° C. The zeta potential (mV), particle size (nm), conductivity (μS/cm), and pH were monitored over the course of the 8 weeks, and the results are set forth in FIGS. 2A-2E.

As is apparent from the results set forth in FIGS. 2A-2E, Polishing Compositions 5A-5E maintained a stable zeta potential (mV), particle size (nm), conductivity (μS/cm), and pH over the course of 8 weeks at room temperature (23° C.) and 45° C. These results show that Polishing Compositions 5A-5E, comprising ceria abrasive particles and silica abrasive particles comprising an aminosilane compound, were stable over the course of 8 weeks at room temperature (23° C.) and 45° C.

### Example 6

This example demonstrates the stability of a polishing composition comprising ceria abrasive particles and silica abrasive particles comprising an aminosilane compound, a phosphonium silane compound, or a combination thereof prepared according to the invention.

Polishing Compositions 6A-6C, used in this example, were prepared by combining 0.29 wt. % ceria abrasive particles and 0.095 wt. % silica abrasive particles. Polishing Composition 6A contained Silica Abrasive A—silica abrasive particles comprising an aminosilane compound internal to an outer surface thereof with an average particle size of about 50 nm, a zeta potential of about 20 mV, and a molar ratio of the aminosilane compound to silica of approximately 10%. Polishing Composition 6B contained Silica Abrasive B—silica abrasive particles comprising an aminosilane compound internal to an outer surface thereof with an average particle size of about 40 nm, a zeta potential of about 25 mV. Polishing Composition 6C contained Silica Abrasive C-(silica abrasive particles comprising an aminosilane compound internal to an outer surface thereof with an average particle size of about 30 nm, a zeta potential of about 50 mV). All compositions contained picolinic acid (333 ppm at POU), Rocima BT-NV2 (14 ppm at POU) and 0.29% wt. % ceria abrasive particles [colloidal ceria with D_{W}=110-120 nm]. Silica Abrasive A had a larger average particle size than Silica Abrasive B or Silica Abrasive C.

Patterned substrates comprising TEOS, SiN LP (low pressure chemical vapor deposition), SiN PE (plasma enhance chemical vapor deposition), Poly, or A-Si were each polished under identical conditions (i.e., 3 PSI (20.55 kPa) downforce, head speed=85 rpm, platen speed=100 rpm, and total flow rate=150 mL/min). Following polishing, the RR for TEOS, SiN PE, SiN LP, Poly, and A-Si were determined, and the results are set forth in Table 8.

TABLE 8
Polishing Removal Rates of Polishing Compositions 6A-6C

| | TEOS | Poly | A-Si | SiN PE | SiN LP |
|---|---|---|---|---|---|
| | (Å/min) | (Å/min) | (Å/min) | (Å/min) | (Å/min) |
| Polishing | 3106 | 679 | 776 | 15 | 12 |
| Composition 6A | | | | | |
| Polishing | 3520 | 827 | 888 | 18 | 19 |
| Composition 6B | | | | | |
| Polishing | 3390 | 820 | 962 | 14 | 13 |
| Composition 6C | | | | | |

As is apparent from the results set forth in Table 8, increasing the silica abrasive particle size increased the TEOS removal rate while maintaining high Poly removal rate and high A-Si removal rate. These results show that modifying the silica abrasive particle size desirably provides tunability to the removal rate ratio and selectivity between TEOS, Poly, and A-Si without significantly affecting the SiN removal rate.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A chemical-mechanical polishing composition comprising:
(a) about 0.001 wt. % to about 10 wt. % silica abrasive particles comprising an aminosilane compound, a phosphonium silane compound, or a combination thereof incorporated (i) on an outer surface thereof and/or (ii) internal to an outer surface thereof, wherein the silica abrasive particles have a zeta potential of at least 13 mV,
(b) about 0.001 wt. % to about 10 wt. % ceria abrasive particles, wherein the ceria abrasive particles have an average particle size of about 50 nm to about 150 nm, and
(c) water, wherein the polishing composition has a pH of about 1 to about 7.

2. The polishing composition of claim 1, wherein the polishing composition has a pH of about 3 to about 5.

3. The polishing composition of claim 1, wherein the polishing composition comprises about 0.01 wt. % to about 1 wt. % of the silica abrasive particles.

4. The polishing composition of claim 1, wherein the silica abrasive particles have a zeta potential of about 15 mV to about 35 mV.

5. The polishing composition of claim 1, wherein the silica abrasive particles have an average particle size of about 50 nm to about 200 nm.

6. The polishing composition of claim 1, wherein the silica abrasive particles comprise an aminosilane compound, a phosphonium silane compound, or a combination thereof incorporated on an outer surface thereof.

7. The polishing composition of claim 1, wherein the silica abrasive particles comprise an aminosilane compound.

8. The polishing composition of claim 7, wherein the silica abrasive particles comprising the aminosilane compound have a molar ratio of the aminosilane compound to silica of less than 10%.

9. The polishing composition of claim 1, wherein the silica abrasive particles further comprise an alkali catalyst incorporated internal to an outer surface thereof.

10. The polishing composition of claim 9, wherein the alkali catalyst is tetramethylammonium hydroxide or ethyloxypropylamine.

11. The polishing composition of claim 1, wherein the silica abrasive particles and ceria abrasive particles have an aggregate zeta potential of about 20 mV to about 40 mV in the polishing composition.

12. The polishing composition of claim 1, wherein the polishing composition further comprises one or more nitrogen-containing zwitterionic compounds.

13. The polishing composition of claim 1, wherein the silica abrasive particles and ceria abrasive particles have an aggregate average particle size of about 60 nm to about 110 nm in the polishing composition.

14. A method of chemically-mechanically polishing a substrate comprising:
(i) providing a substrate,
(ii) providing a polishing pad,
(iii) providing a chemical-mechanical polishing composition comprising:
(a) about 0.001 wt. % to about 10 wt. % silica abrasive particles comprising an aminosilane compound, a phosphonium silane compound, or a combination thereof incorporated (i) on an outer surface thereof and/or (ii) internal to an outer surface thereof, wherein the silica abrasive particles have a zeta potential of at least 13 mV,
(b) about 0.001 wt. % to about 10 wt. % ceria abrasive particles, wherein the ceria abrasive particles have an average particle size of about 50 nm to about 150 nm, and,
(c) water, wherein the polishing composition has a pH of about 1 to about 7,
(iv) contacting the substrate with the polishing pad and the chemical-mechanical polishing composition, and
(v) moving the polishing pad and the chemical-mechanical polishing composition relative to the substrate to abrade at least a portion of the substrate to polish the substrate.

15. The method of claim 14, wherein the silica abrasive particles comprise an aminosilane compound, a phosphonium silane compound, or a combination thereof incorporated on an outer surface thereof.

16. The method of claim 14, wherein the silica abrasive particles comprise an aminosilane compound, a phosphonium silane compound, or a combination thereof incorporated internal to an outer surface thereof.

17. The method of claim 14, wherein the silica abrasive particles comprise an aminosilane compound.

18. The method of claim 17, wherein the silica abrasive particles comprising the aminosilane compound have a molar ratio of the aminosilane compound to silica of less than 10%.

19. The method of claim 14, wherein the silica abrasive particles further comprise an alkali catalyst incorporated internal to an outer surface thereof.

20. The method of claim 19, wherein the alkali catalyst is tetramethylammonium hydroxide or ethyloxypropylamine.
